(19) United States
(12) Patent Application Publication
(10) Pub. No.: US 2020/0235245 A1
(43) Pub. Date: Jul. 23, 2020

(54) FLEXIBLE ELECTRONIC COMPONENTS AND METHODS FOR THEIR PRODUCTION

(71) Applicants: Cambridge Enterprise Limited; Jiangnan University

(72) Inventors: Felice Torrisi, Cambridge (GB); Tian James Carey, Cambridge (GB); Chaoxia Wang, Wuxi, Jiangsu (CN); Jiesheng Ren, Wuxi, Jiangsu (CN)

(21) Appl. No.: 16/334,675

(22) PCT Filed: Sep. 20, 2017
(86) PCT No.: PCT/EP2017/073827

§ 371 Date: Mar. 19, 2019

(30) Foreign Application Priority Data
Sep. 22, 2016 (GB) 1616140.8
Apr. 10, 2017 (GB) 1705742.3

(51) Int. Cl. H01L 29/786; H01L 29/267; H01L 23/31; H01L 21/02; H01L 29/45; H01L 29/66; H01G 11/36; H01G 11/26; C09D 11/54; C09D 11/52; C09D 11/322; C09D 11/037; D06P 5/30; D06P 5/00; D06M 11/74; D06M 11/58; D06M 13/463; D06M 13/467; D06M 15/564

(52) U.S. Cl. CPC H01L 29/78603; D06M 2101/32; H01L 23/3171; H01L 21/02527; H01L 21/02422; H01L 21/0254; H01L 29/45; H01L 29/66522; H01L 21/02623; H01L 29/78696; H01G 11/36; H01G 11/26; C09D 11/54; C09D 11/52; C09D 11/322; C09D 11/037; D06P 5/30; D06P 5/002; D06M 11/74; D06M 11/58; D06M 13/463; D06M 13/467; D06M 15/564; H01L 29/267

(57) ABSTRACT

A flexible electronic component in this disclosure comprises a flexible fabric substrate and a smoothing layer formed on the flexible fabric substrate. A layer of nanoplatelets derived from a layered material is deposited on the smoothing layer by inkjet printing. The layer of nanoplatelets may form a first layer of a first nanoplatelet material and there may be provided at least a second layer, of a different nanoplatelet material, formed at least in part on the first layer. First and second electrodes are provided in contact respectively with the first and second layers.

The work leading to this invention has received funding from the European Union's Seventh Framework Programme (FP7/2007-2013) under grant agreement number 319277.

### BACKGROUND TO THE INVENTION

### Field of the Invention

The present invention relates to the field of textiles and has application, for example, in wearable electronics, smart fabrics and e-textiles. In particular, but not exclusively, it relates to the field of depositing layered materials onto textiles. One example of a suitable layered material is graphene.

### Related Art

Wearable electronics, smart fabrics and e-textiles have the potential to reshape the electronics markets over a wide range of sectors, spanning from biomedical through to fashion-tech. Fabric-integrated components and devices, and innovative textiles which can conduct electricity, and/or guide and/or emit light, and/or regulate temperature are at the centre of a new technical advance in the smart textile industry.

Currently, most wearable electronics are based onto two main technologies. The first technology is that of standard rigid electronic components (e.g. light emitting diodes, transistors, microchips, batteries, etc.) embedded, attached, or simply interconnected to fabrics or textiles using classic metallic (silver, gold, copper, nickel) wire bonding techniques or flexible textile-coated metallic wires. The second technology is that of flexible electronic components integrated into textiles and fabrics by interwoven flexible metal/polymer conductive wires.

Metallic wires and metal-polymer composites are expensive, heavy and require an accurate weaving process to be incorporated into the fabric. Moreover metals tend to oxidize and have a strong dependence of conductivity to temperature and humidity rate, which may affect the reliability and robustness of the wearable circuits and devices. Fibres containing a high density of metal may also limit the mechanical performance of fibres by a reduction in flexibility and a reduction in elongation at break. Use of both metals and organic polymers may affect the bio-compatibility of the fibres, for example, metals such as nickel have shown poor bio-compatibility and allergenic effects that make them not desirable for use in wearable fabrics.

Printing has evolved from a tool for text and graphics [DeGans et al. 2004], to a milestone for rapid manufacturing of plastic electronics [Van Osch et al. 2008] and is now an established technique to print electrodes and interconnections, based on metal nanoparticles [Singh et al. 2010], and electronic devices such as thin film transistors (TFTs) based on organic conducting and semiconducting inks [Sekitani et al. 2009, Sirringhaus et al. 2000]. However, the operation speed of organic TFTs, which is defined in terms of electron mobility, is still much lower than state of the art silicon technology. Several approaches have attempted to coat/print on textiles and fabrics with metallic inks [Jost et al. 2011] and/or organic conducting/semiconducting inks. Printed components based on metal nanoparticle and organic inks are expensive, tend to oxidize and generally require post-printing treatments. Several approaches aiming to improve these results encompass carbon-based inks typically containing particles of amorphous carbon, carbon black or graphite that are suspended in a solvent via binder or surfactant. However the presence of binders or surfactants can affect the final conductivity, requiring further post-printing treatment.

Graphene and related materials (GRMs) are a group of two-dimensional layered materials, including, but not limited to, metals (e.g., NiTe₂, VSe₂), semi-metals (e.g., WTa₂, TcS₂), semiconductors (e.g., WS₂, WSe₂, MoS₂, MoTe₂, TaS₂, RhTe₂, PdTe₂, black phosphorus), insulators (e.g. h-BN), superconductors (e.g., NbS₂, NbSe₂, NbTe₂, TaSe₂), topological insulators and thermo-electrics (e.g., Bi₂Se₃, Bi₂Te₃), transition metal dichalcogenides (TMDs) and transition metal oxides (TMOs). GRMs can have unique mechanical, electrical and optical properties. In many cases they also have exceptional environmental stability (low moisture absorption) and potential for low-cost production enabling fully flexible printed flexible electronics and photonics. This places GRMs as prime candidates to play a major role in the wearable electronics and smart textiles sectors, where classical cotton, silk, and other natural or synthetic fabrics can be transformed into advanced active textiles exhibiting electrical, optical and/or smart thermal functions.

WO2014/064432 discloses the manufacture of inks comprising a carrier liquid with a dispersion of flakes derived from a layered material. However, the present inventors have realised, as part of their contribution to the art forming part of this disclosure, that the production of electronic components on a flexible fabric substrate using such ink presents a number of problems. These include including poor adhesion of the ink to the substrate, poor connectivity across layers due to substrate roughness, unwanted absorption of carrier fluid by fabric substrate leading to poor quality deposited layers, and poor durability and washability of the deposited inks.

### SUMMARY OF THE INVENTION

As discussed above, the inventors have found that simple deposition of graphene or, more generally, GRM (graphene and related material) ink onto a fabric substrate can result in a rather poor quality deposited layer. The inventors consider that this is partly due to a lack of affinity between the fabric and the 2D material. Additionally, there may also be a lack of long-range connectivity between nanoplatelets in the deposited layer caused by the high surface roughness (>50 μm) of typical fabrics used for clothing. This roughness is caused by the weave of the fabric, and/or by the inherent roughness of the fibres and/or yarns of the fabric. The lack of chemical affinity between the fabric and the 2D material can also result in a somewhat random nanoplatelet arrangement within the deposited layer, which may be undesirable.

Furthermore, whilst it is acknowledged that printing of graphene-based inks onto non-fabric substrates is known, binders and surfactants are generally used in such inks. However, the presence of such components, and particularly the presence of substantial quantities of such components in the inks may affect the final properties of a deposited graphene or, more generally, GRM layer. For example, such components may affect the optical, mechanical and electrical properties of the layer, and in some cases may necessitate post-printing treatment, which is disadvantageous. Therefore, it is preferable that no such additives are used, although some small amount may be acceptable.

It is known to treat fibres and/or fabrics to improve dyeability. WO 2014/116230 for example discloses a method of treating a cellulose fibre including the steps of contacting the fibre with a solution, the solution comprising about 0.5 to about 15 g/L of a wetting agent, about 5 to about 150 g/L of an alkaline composition, and about 5 to about 200 g/L of an ammonium salt, wherein a permanent positive charged (cationized) site on the cellulose molecule which can attract an anionic (negatively charged) compound such as an anionic dyestuff. However, this prior art is concerned with dyebility, specifically the ability to achieve a desired colour, along with preventing problems such as colour bleeding and fading, rather than aiming to provide improved deposited functional layers, which is one preferred object of the present invention.

Accordingly, the present inventors consider that there is an unmet need in the prior art, to develop improved functional layers for flexible functional components, such as flexible electrical components. Flexibility of the components here includes flexibility in response to compression, tension, buckling and/or torsion.

The present invention has been devised in order to address at least one of the above problems. Preferably, the present invention reduces, ameliorates, avoids or overcomes at least one of the above problems.

Accordingly, in a first preferred aspect of the invention, there is provided a flexible electronic component comprising a flexible fabric substrate, a smoothing layer formed on the flexible fabric substrate and a coating comprising a deposited layer of nanoplatelets derived from a layered material formed on the smoothing layer.

In a second preferred aspect, the present invention provides a method for producing a flexible electronic component, the method including the steps;
treating a flexible fabric substrate to provide an intermediate smoothing layer on at least a part of the flexible fabric substrate;
providing an ink comprising a dispersion of nanoplatelets suspended in a carrier liquid, the nanoplatelets being derived from a layered material;
applying the ink to at least a part of the intermediate smoothing layer to produce the electronic component.

In a third aspect of the invention, there is provided a flexible electronic component or device, obtained or obtainable by a method according to the second aspect.

Any of the first, second and third aspects of the invention may be combined with each other. The first, second and/or third aspects of the invention may have any one or, to the extent that they are compatible, any combination of the following further optional features.

In some embodiments, the method includes the step of treating at least a part of the flexible fabric substrate to provide a treated portion wherein the treated portion is cationized or anionized. In this case, the treated portion at least partly corresponds to the location of the flexible electronic component.

Thus, in some embodiments, at least part of an interface of the fabric on which the coating is deposited is a cationized or anionized treated portion.

Cationization treatment of the fabric provides a positive charge at the surface of the fabric. Anionization treatment of the fabric provides a negative charge at the surface of the fabric. It has been found that this may enhance uniformity of a nanoplatelet-based ink coating applied to a fabric or textile substrate. Without wishing to be bound by theory, the inventors suggest that this is due to electrostatic interactions between the treated fabric and the nanoplatelets in the ink. For example, the treated portion of the textile surface may attract nanoplatelets which have an opposite charge through electrostatic interactions. For the case of non-functionalised GRMs, these may have varying affinity with the cationized or anionized fabrics depending on their terminal groups. Providing a more uniform ink coating on a flexible fabric substrate has advantages in that it may improve the functionality of the ink coatings by, for example, improving the connectivity of the deposited nanoplatelets and therefore decreasing the sheet resistance of the applied ink coating.

In some embodiments, the nanoplatelets are functionalized. There may be included a step of functionalizing the nanoplatelets, for example, before the ink comprising the dispersion of nanoplatelets is applied to the fabric substrate.

Functionalization of the nanoplatelets may include functionalization to exhibit positive or negative charges on the surfaces of the nanoplatelets. Alternatively it may include functionalization by adding functional groups to the nanoplatelets. Functionalisation of the nanoplatelets can impose a termination with a desired charge polarity. An appropriate functionalization process may be selected according to the selected nanoplatelets materials in the ink, and the intended final properties of the electronic component. Such functionalization of the nanoplatelets may increase electrostatic interaction between the nanoplatelets and the treated portion of the flexible fabric substrate. This can lead to improved uniformity of an ink coating on a flexible fabric substrate, and accordingly improve desirable of the deposited coating. For example, when the nanoplatelets are formed of graphene, these may be functionalised by chemical oxidation and reduction using a modified Hummers method. Alternatively, intercalation of graphite can also lead to formation of functional groups. Treatment with metal salts such as gold chloride, iron chloride or other suitable reagents can generate modification of the in-plane or edge termination of graphene. Another method of achieving chemically functionalised graphene is graphene flake growth by methane cracking in a high temperature furnace.

Preferably, the step of treating the at least a part of a surface of the flexible fabric substrate includes a step of contacting the at least a part of a surface of the flexible fabric substrate with a solution comprising 3-chloro-2-hydroxypropyltrimethylammonium chloride, bis-quaternary ammonium salt, or polymerizable bis-quaternary ammonium salt. More generally, the step of treating the at least a part of the flexible fabric substrate may include a step of contacting the at least a part of flexible fabric substrate with a solution comprising one or more quaternary ammonium salt.

The nanoplatelets may be derived from any suitable layered material. Of particular interest are graphene and related materials (GRMs). This is due to the useful properties of such materials as discussed above, in particular their mechanical, electrical, optical and thermal properties. Graphene and related materials are a group of two-dimensional layered materials, including, but not limited to, metals (e.g., NiTe₂, VSe₂), semi-metals (e.g., WTa₂, TcS₂), semiconductors (e.g., WS₂, WSe₂, MoS₂, MoTe₂, TaS₂, RhTe₂, PdTe₂, black phosphorus), insulators (e.g. h-BN), superconductors (e.g., NbS₂, NbSe₂, NbTe₂, TaSe₂) and topological insulators, thermo-electrics (e.g., Bi₂Se₃, Bi₂Te₃), transition metal dichalcogenides (TMDs), transition metal oxides (TMOs), and other two-dimensional materials such as graphite.

In some embodiments, there may be provided sub-layers of different nanoplatelet materials. Additionally or alternatively two or more different nanoplatelet materials may be combined with each other in one layer. For example, the device may include a first sub-layer of a first nanoplatelet material and a second sub-layer of a second nanoplatelet material, different in composition from the first nanoplatelet material. The second sub-layer may be deposited at least in part on the first sub-layer. A third sub-layer of a third nanoplatelet material may be provided, different from at least one of the first and second nanoplatelet materials. The third sub-layer may be deposited at least in part on the second and/or first sub-layer. In this way, electronic devices may be formed, having functionality determined at least in part by the interaction of the first, second and/or third layers at their respective interfaces. Additionally or alternatively, multiple sub-layers of the same nanoplatelet material may be deposited. This can help to ensure that a sufficient thickness is deposited.

In some embodiments, the electronic component is a thermoelectric device.

Preferably, liquid phase exfoliation (LPE) is used as a production method for producing the nanoplatelets used in the ink in this invention. This is because LPE is able to provide nanoplatelets in a convenient form (for example, dispersions, inks or pastes). LPE is also compatible with large scale production (e.g. is capable of producing quantities of nanoplatelets greater than 1 kg). LPE is capable of giving high yields of single layer flakes (up to 80%). It is also a relatively low cost manufacturing process. Whilst LPE is the preferred manufacturing method, any other manufacturing method which provides GRMs of sufficient quality for use in the invention may be used. GRMs produced by LPE, including WS₂, MoO₃ and BN have diverse properties, e.g. metallic, semiconducting, insulating, electrochemically active, etc. making them suitable functional agents for inks suitable for a wide range of textiles.

Suitable inks of GRMs may be obtained by processes outlined in WO2014/064432, the entire contents of which are here incorporated by reference. The preferred composition of the ink will vary depending on the desired device properties, and different inks containing different GRMs may be used in the manufacture of a single flexible electronic device, for example, for production of a multilayer structure. GRM inks may also be mixed, to enable precise selection of ink properties.

Suitable nanoplatelets derived from a layered material may be considered to be those with lateral size of 1, 2, 3, or 3 or more microns and thicknesses below 100 nm.

Different ink deposition methods (some examples of which include inkjet, flexographic, gravure, spray coating, rod coating, roll to roll coating, slot-dye coating, spin coating, transfer printing, dip coating and screen printing) may be used to produce flexible electronic components or devices of the invention. Different deposition methods may offer different final properties and/or structures of the flexible components or devices. Preferably therefore, the deposition method is selected according to the desired properties of the electronic component or device to be produced.

Different nanoplatelet dispersions for different inks may be selected depending on the deposition process to be used. For example, the viscosity of the ink, the mass % of nanoplatelets in the dispersion, or any other suitable parameters of the ink may be varied, depending on the intended deposition process to be used, and the intended properties of the device to be produced. Typical suitable viscosity ranges for some example printing or coating processes are as follows: Inkjet printing 1-20 mPa s, flexo and gravure printing 150-200 mPa s, spray coating 1-200 mPa s, screen printing 1000 mPa s. For all deposition processes, it is generally preferable to use an ink with higher mass % of nanoplatelets in the dispersion, as this may provide for higher quality deposited layers.

In some preferred embodiments, the ink includes no binder and/or surfactant. However, in some cases, small quantities of one or more such additives may be advantageous, without compromising the performance of the deposited layer. For example, the ink may include 0.1 g/L of such additives. Preferably, the ink includes not more than 10 g/L of such additives.

As defined above, to create a more uniform surface for subsequent printing processes, the fabric is treated with an intermediate smoothing layer. The smoothing layer may also be referred to as a planarization layer. This layer may be applied to the fabric for example by bar coating or screen printing. The smoothing layer may reduce a relatively high surface roughness of a fabric by filling-in the weave of the fabric and offering a surface of reduced roughness to which a GRM ink may then be applied. A particularly appropriate material for this smoothing layer is polyurethane, however any other suitable material may be used, for example silane coupling agent or soft adhesion agent.

The root mean squared roughness Rq of this smoothing layer is preferably <300 μm, more preferably <100 μm, more preferably <50 μm, even more preferably <10 μm and most preferably <5 μm.

The fabric substrate, optionally including the intermediate smoothing layer, may then be chemically modified as described above, to provide a higher surface energy, increasing the interaction strength between the substrate and the GRM ink flakes, promoting formation of a more uniform deposited layer.

Several flexible interlayers may be used to protect the GRM flexible electronic components, providing improved durability and washability. For example, a flexible polymer interlayer may be bar coated on top of the deposited ink layer to protect the GRM flexible electronic component and assist in preserving the electrical, optical and mechanical properties. This process may be advantageous when it is intended to produce wearable, environmentally stable and durable smart textiles. Such flexible interlayers may be applied by any method as discussed previously. Suitable materials include, for example, polyurethane, or any other material which provide a suitable degree of protection for the GRM printed structures, including, for example, silane coupling agents. One or more additional layers of suitable 2D materials, as listed above, can be used for such a protective function. For example, an h-BN layer is suitable, providing protection to the layers below from oxygen and/or water vapour.

The type of fabric used as a substrate for such flexible electronic device is not particularly limited, however it may be preferable to use cotton, or cotton blended yarns, which has reactive groups, relatively complicated surface morphology, good flexibility, and relatively high porosity, in addition to being a commonly used textile in clothing. The wide use of cotton fibres in diversified outdoor and indoor-applications along with its traditional textile products can be mainly attributed to its economical, eco-friendly, biodegradable and hydrophilic nature (—OH). With an understanding of the structure of cotton, there can be provided control over its modification. The chemical stability of the cotton molecule is considered to be determined by the sensitivity to hydrolytic attack of the β-1,4-glycosidic linkages between the glucose repeating units.

Printed GRM inks on textiles can be used to fabricate flexible, conductive and wearable electronic components and devices in many different forms, some examples being circuits, interconnections, sensors (including, for example, movement, pressure or temperature sensors), capacitors, transistors, displays, antennas, batteries, photodetectors etc.

The invention therefore has a wide range of industrial applications, including fashion dress, military garment devices, high-performance sportswear and personal health monitors, wearable computers, energy harvesting/storage devices directly incorporated into clothes, and many more areas besides.

Preferably the deposited layer of nanoplatelets can be considered to form a first layer of a first nanoplatelet material. There is preferably provided at least a second layer, of a different nanoplatelet material, formed at least in part on the first layer.

There may be additionally provided at least first and second electrodes, in contact respectively with the first and second layers.

In some preferred embodiments, the flexible electronic component may be in the form of a transistor. For example, the flexible electronic component may be in the form of a field effect transistor.

In some embodiments, the first layer may be formed of graphene. As mentioned above, the second layer may be formed of a different material. One suitable different material is h-BN. The first layer may be provided with source and drain electrodes. The second layer may be provided with a gate electrode. Thus, preferably, the source, drain and gate electrodes are separated from the interface between the first layer and the second layer.

Alternatively, in some embodiments, the first layer may be formed of h-BN. The second layer may be formed of graphene. The first layer may be provided with a gate electrode. The second layer may be provided with source and drain electrodes. Thus, preferably, the source, drain and gate electrodes are separated from the interface between the first layer and the second layer.

The flexible electronic component may have a charge carrier mobility of at least 50 cm²/Vs. More preferably, the charge carrier mobility is at least 60 cm²/Vs. Still more preferably, the charge carrier mobility is at least 70 cm²N/s.

As will be understood, if required, many different layers can be deposited in a required structural arrangement in order to form a required electronic device.

With respect to the fabric on which the flexible electronic component is formed, preferably the fabric, before application of the smoothing layer, has a roughness Rq of 35 μm or less. More preferably, Rq is 30 μm or less.

A suitable fabric for use with embodiments of the invention has been found to be polyester satin.

In some embodiments, the smoothing layer is formed from polyurethane. However, different approaches can be taken to the formation of the smoothing layer. For example, the smoothing layer may comprise a first sub-layer of polyurethane and a second sub-layer of h-BN. The layer of h-BN may provide additional functionality, being for example a functional layer of the flexible electronic component.

Preferably, the thickness of the smoothing layer is at least 5 μm. In some embodiments, the thickness of the smoothing layer may be greater, e.g. at least 10 μm. The smoothing layer should preferably not be so thick as to significantly affect the performance of the underlying fabric. For example, the smoothing layer is preferably not more than 100 μm thick, still more preferably not more than 80 μm thick, or not more than 60 μm thick, or not more than 40 μm thick.

The flexible electronic component may further comprise a washable protective layer formed over the device. The washable protective layer may for example be a flexible polymer layer. It is found in some embodiments that the combination of flexibility and the washable protective layer has the effect that the flexible electronic component can survive multiple washing cycles (e.g. typical domestic washing cycles) without significant degradation of the performance of the flexible electronic component.

Preferably, the intermediate smoothing layer applied to the fabric substrate has a surface roughness Rq of less than 10 μm. More preferably, Rq is less than 8 μm. Still more preferably, Rq is less than 6 μm. Still yet more preferably, Rq is less than 5 μm.

In some embodiments, multiple sub-layers of the same nanoplatelet material are deposited, in order to build up a required thickness for the nanoplatelet material layer. Similarly, in some embodiments, the intermediate smoothing layer is formed by deposition of multiple sub-layers, in order to build up a required thickness for the intermediate smoothing layer.

In some embodiments, the smoothing layer may function as an adhesive layer, adhering the subsequent layers with respect to the fabric.

Preferably, the ink is applied to the at least a part of the treated portion of the fabric substrate by inkjet printing.

It is to be understood that this disclosure provides approaches for the formation of different types of flexible electronic device, of different structure and of different degrees of complexity. At a simple level, the disclosure allows the formation of flexible electrical interconnects. At another level, the disclosure allows the formation of a photodetector device (for example). At still another level, the disclosure allows for the formation of a transistor device (for example). Still further, the disclosure allows for the formation of entire or partial electrical circuits, formed of a few or many flexible electronic components. The disclosure therefore permits the formation of integrated printed circuits on textile.

Further optional features of the invention are set out below.

### BRIEF DESCRIPTION OF THE DRAWINGS

Embodiments of the invention will now be described by way of example with reference to the accompanying drawings in which:

FIG. 1 (a) shows root mean square (Rq) roughness measurements of the planarization layers, measured used a stylus profilometer (Bruker DektakXT), the horizontal axis identifying different sample numbers;

FIG. 1 (b) shows profilometry measurements of a polyester fabric with and without a polyurethane coating (smoothing layer), the vertical axis not being labelled with units, since the figure simply provides a comparison between the profiles of the two surfaces;

FIG. 2 shows a graph of viscosity (Pa s) against shear rate (l/s) for a Graphene-Ethanol ink;

FIG. 3 shows a surface tension measurement using the pendant drop method (FTA FTA1000B). The shape of the drop results from the relationship between the surface tension and gravity. The surface tension is then calculated from the shadow image of a pendant drop using drop shape analysis;

FIG. 4 shows a TEM micrograph of a single-layer graphene flake and a few layer graphene flake from a graphene-ethanol (Gr-Eth) ink dispersion;

FIG. 5 shows (a) an atomic force microscopy (AFM) topographic image of typical flakes in the Gr-Eth dispersion; and (b) a corresponding cross-sectional profile taken along the dashed line of FIG. 5(a).

FIG. 6 shows (a) the flake lateral size distribution and (b) the apparent thickness for a Gr-Eth ink dispersion.

FIG. 7 shows ultraviolet-visible spectroscopic absorption spectra for Gr-DiW, Gr-NMP, Gr-Eth, and Gr-Eth-HC ink dispersions at concentrations of 9.7, 9.6, 0.36 and 10 mg/mL respectively.

FIG. 8 shows a micrograph of an inkjet printed graphene conductive interconnection on cotton fabric with a polyurethane smoothing layer;

FIG. 9 shows Raman spectra acquired at 514.5 nm of Gr-Eth deposited layer in (a) the ink-jet printed sample of FIG. 8 and (b) a dip coated sample;

FIG. 10 shows scanning electron microscopy (SEM) images of (a) cotton fabric before treating and coating and (b) the same fabric after dip-coating in an ink containing a dispersion of nanoplatelets derived from a layered material.

FIG. 11 shows the resistance (MO) of 1 cm² of cotton fabric dip-coated in Gr-Eth-HC ink as a function of number of washing cycles.

FIG. 12 shows graphs of (a) frictional force (N) against normal (N) for an AFM scratch test for each sample FF_sam_1-8; and (b) coefficient of friction range and average value for each sample FF_sam_1-8;

FIG. 13 shows (a) strength (MPa) for the fabric samples reported in Table 2 and (b) strain at break for the fabric samples reported in Table 2;

FIG. 14 shows (a) Max load (N) for each bundle of fabric sample fibres and (b) strain at break for each bundle of fabric sample fibres.

FIG. 15 shows optical absorption spectroscopy for the graphene and h-BN inks.

FIG. 16 shows an AFM image of a typical flake produced from LPE graphene ink.

FIG. 17 shows a cross sectional profile of the flake of FIG. 16.

FIG. 18 shows an AFM image of a typical flake produced from microfludised h-BN ink.

FIG. 19 shows a cross sectional profile of the flake of FIG. 18.

FIG. 20 shows AFM statistics indicating thickness distribution for the graphene and h-BN inks.

FIG. 21 shows AFM statistics indicating lateral flake size distribution for the graphene and h-BN inks.

FIG. 22 shows SEM statistics of the graphene and h-BN flakes.

FIG. 23 shows a scanning electron microscopy image of the graphene flakes of lateral size about 200 nm. An image of a representative starting graphite particle (unexfoliated) of lateral size about 400 μm is shown in the inset.

FIG. 24 shows an SEM image of the h-BN flakes of lateral size about 516 nm. An image of a representative starting bulk h-BN particle (unexfoliated) of lateral size about 5 μm is shown in the inset.

FIG. 25 shows a transmission electron microscopy (TEM) image of few layer h-BN.

FIG. 26 shows a transmission electron microscopy (TEM) image of few layer graphene.

FIG. 27 shows TEM statistics indicating the lateral size distribution of the few layer graphene and few layer h-BN.

FIG. 28 shows a schematic view of a capacitor heterostructure.

FIGS. 29-31 show optical microscopy images of three fabrication steps for forming capacitors fully by inkjet printing.

FIG. 32 shows stylus profilometry of the h-BN thickness as a function of printing passes.

FIG. 33 shows typical impedance spectra for each capacitor obtained which follows a R—C equivalent circuit model [Kelly et al (2016)].

FIG. 34 shows the capacitance variation with number of printed layers for the capacitor.

FIG. 35 shows a schematic cross sectional view of a printed FET heterostructure, formed on a PET films.

FIG. 36 shows Raman Spectroscopy of the printed structure indicated in FIG. 35.

FIGS. 37 and 36 show HAADF-STEM cross sectional views of the device at the locations indicated in FIG. 35.

FIG. 39A shows a schematic cross sectional view of a textile based capacitor with graphene/h-BN/graphene heterostructure.

FIG. 39B shows typical impedance spectra of the capacitive structure of FIG. 39A.

FIG. 40 shows a schematic view of a printed coplanar TFT heterostructure on PET.

FIG. 41 shows a schematic view of a printed inverted staggered TFT heterostructure on PET.

FIG. 42 shows an optical micrograph (dark field) of the printed coplanar TFT heterostructure on PET. The channel length is 50 μm.

FIG. 43 shows an optical micrograph (dark field) of the printed inverted staggered TFT heterostructure on PET. The channel length is 65 μm.

FIG. 44 shows the transfer characteristic of the FET heterostructures as a function of Vds.

FIG. 45 shows the transfer characteristic of the FET heterostructures with observable hysteresis depending on sweep direction at Vds=1V.

FIG. 46 shows the linear output characteristic of the heterostructures.

FIG. 47 shows the transfer characteristic as a function of bending radius at V_{ds}=1 V.

FIG. 48 shows the evolution of the transfer characteristic over a 2 year period at V_{ds}=50 mV.

FIG. 49 shows the “roughness” (determined with a profilometer) of five different fabric materials.

FIG. 50 shows profilometry data indicating Rq of the planarization layers.

FIG. 51 shows profilometry data indicating Rq of the polyurethane planarization layer as a function of coating passes.

FIG. 52-55 show the sequence of steps in the inkjet printing for fabrication of a TFT heterostructure on fabric.

FIG. 56 shows a schematic cross sectional view of a printed inverted staggered TFT heterostructure on fabric.

FIG. 57 shows a FIB-SEM cross sectional view of the device through the left contact shown in FIG. 56.

FIG. 58 shows a FIB-SEM cross sectional view of the device through the middle channel shown in FIG. 56.

FIG. 59 shows a FIB-SEM cross sectional view of the device through the right contact shown in FIG. 56.

FIG. 60 shows the transfer characteristic of the t of about 100 nm graphene thickness textile TFT at Vds=1.

FIG. 61 shows the field effect mobility as a function of washing cycles for the t of about 200 nm graphene thickness textile TFT.

FIG. 62 shows an optical micrograph of the inverted FET on polyester with a channel length of 80 μm.

FIG. 63 shows transfer characteristics of the textile FET at Vds=1.

FIG. 64 shows output characteristics of the textile FET at Vds=1.

FIG. 65 shows the transfer characteristic of the textile FET as a function of bending radius at V_{ds}=1 V.

FIG. 66 shows the transfer characteristic of the textile FET before and after 20 washing cycles V_{ds}=1 V.

FIG. 67 shows an image obtained using optical microscopy (dark field) of an integrated circuit demonstrating an all inkjet-printed complementary graphene inverter.

FIG. 68 shows a schematic of the integrated circuit of FIG. 67.

FIG. 69 shows a circuit diagram of a multifunctional printed logic gate with two inputs (A and B) and one output (OUT) with truth table of an OR logic gate.

FIG. 70 shows a schematic of a memory cell capable of being fully inkjet printed.

### DETAILED DESCRIPTION OF THE PREFERRED EMBODIMENTS, AND FURTHER OPTIONAL FEATURES OF THE INVENTION

In this detailed description, various specific conditions, starting materials, processing equipment, analytical equipment, etc., are specified. However, it will be understood by the skilled person that different specific conditions, starting materials, processing equipment, analytical equipment, etc., can be used and yet substantially the same result achieved based on the general teaching provided by this disclosure.

### Modification of Textile Surfaces

In the present invention, two main types of modification techniques are used to modify the fabric substrates to promote adhesion of nanoplatelets in the ink dispersion to the fabric substrates and accordingly improve the quality of deposited ink layers. The first type of modification uses application of a smoothing or planarization layer to decrease the roughness of the fabric substrate. The second type of modification uses cationization or anionisation of at least a part of the fabric substrate to increase the affinity between deposited nanoplatelets and the fabric substrate. These two modification techniques may also be combined; i.e. a fabric substrate may first have a smoothing layer applied, and then may also undergo cationization or anionisation of at part of the substrate to further promote adhesion of the nanoplatelets on deposition.

### Typical Method for Application of Smoothing Layer:

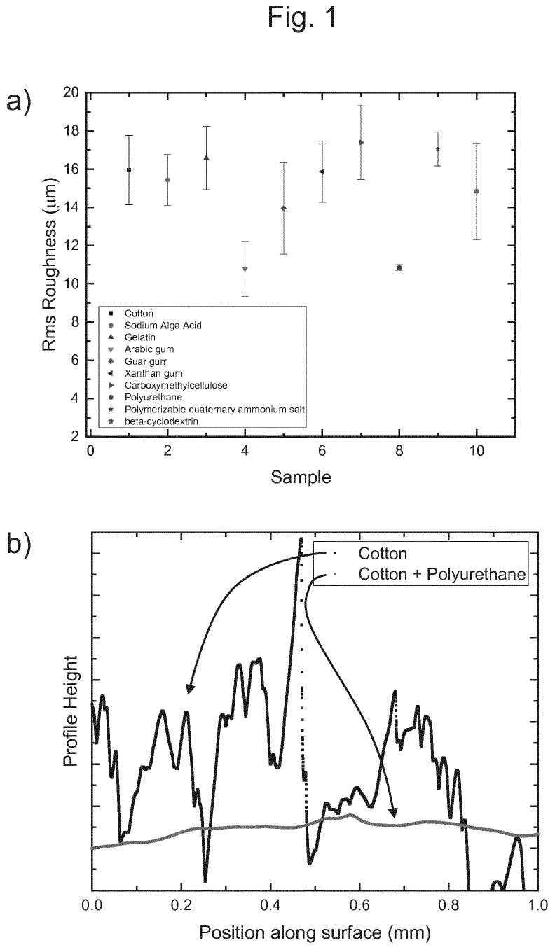

Samples of fabric may be coated with polyurethane or a similar planarization material listed in FIG. 1a by rod coating using a K202 RK coating machine (0.3 um diameter grooves). After coating the fabric can be put into an oven at e.g. 60° C. to cure the polyurethane for e.g. 20 min. The above process can repeated to obtain multiple coating layers. In some cases, for example where the fabric substrate is particularly rough, it may be preferable to apply multiple sequential smoothing layers.

FIGS. 1 (a) and (b) show the effect of applying a smoothing or planarization layer to a Poplin 100% cotton fabric substrate. FIG. 1(a) shows the root mean square (Rq) roughness measurements of the planarization layers, measured used a stylus profilometer (Bruker DektakXT), for a number of different planarization layer materials. When fabrics are coated with polyurethane, the roughness of the fabric with the smoothing layer can be reduced to around 5 μm.

FIG. 1 (b) shows profilometry measurements of a polyester fabric with and without a polyurethane coating (smoothing layer) formed of 5 sequentially deposited layers of polyurethane. The presence of the polyurethane coating reduces overall variation in surface profile across the sample.

### Chemical Treatment for Cationization or Anionisation of Fabrics:

Textiles and fibres can be chemically modified to increase the affinity between the fabric and the GRM nanoplatelets, thus aiding the formation of a uniform GRM coating of the textile. For example, the fibres may be positively or negatively charged, increasing the electrostatic attraction between the fibres and the GRM nanoplatelets. Chemical modification of the fibre can be performed by acid treatment using, for example but not limited, to 3-chloro-2-hydropropane-sulfonic acid sodium (CHSAS) and monochloroacetic acid (MCAA) or 3-chloro-2-hydroxypropyl)trimethylammonium chloride. (CHPTAC). Other suitable reagents for cationization modification of textiles include bis-quaternary ammonium salt, or polymerizable bis-quaternary ammonium salt. Suitable reagents for anionization modification of textiles include surfactants with functional terminating groups such as sulfate, sulfonate, phosphate and carboxylates. However any reagent which is able to provide suitable cationization or anionization of the fabric may be used.

A cationization of the fabric may be performed using (3-chloro-2-hydroxypropyl)trimethylammonium chloride (CHPTAC) (35 g/L) (or a suitable replacement material as discussed above) and dissolved in deionized water at a water/cotton weight ratio of 15:1 respectively. The fabric is immersed in the chemical solution and left on a hot plate at 40° C. for 20 min while gentle stirring is applied. The fabric is then removed and lightly hand squeezed to remove excess water. The treated fabric is then sealed between polyethylene film, placed in a plastic bag and stored in an oven at 40° C. for approximately 24 h. After rinsing the treated fabric a few times with deionized water, the fabric is immersed in an aqueous acetic acid solution (1 g/L) for 5 minutes to neutralize the alkalinity. The fabric again rinsed in deionized water and oven dried overnight at 40° C.

### Graphene and GRM Production

The preferred graphene/GRM production method is LPE, however other suitable production methods may be used. LPE involves the production of 2D materials (by ultrasonication, high shear mixing or microfluidic processing) by exfoliation of bulk layered materials. The exfoliation process is generally performed in aqueous solution containing a stabilising agent (surfactant, polymer or other wrapping agent) or an organic solvent whose surface tension substantially matches the 2D material surface energy. After the exfoliation process, the resulting flakes have a thickness and lateral size distribution which may vary depending on the length, power, or type etc. of exfoliation technique used.

The yield of single layer graphene flakes after ultrasonication process has been demonstrated to reach up to 35% [Torrisi et al. 2012] in NMP and up to 80% in aqueous solution. Lower yields (up to 3%) for single layer graphene flakes have been shown in surfactant aided aqueous-based dispersion exfoliated by high shear mixing. Concentrations of GRM nanoplatelets (nanoplatelets here being defined as those with lateral size being a few microns and thicknesses being below 100 nm) up to 50 g/L have been demonstrated by high shear mixing process [Paton et al. 2014]. Graphene and functionalized graphene composed of graphene nanoplatelets (few layer graphene with aspect ratio of 1:200 in thickness:diameter) powder can also be used and dispersed in liquid by solution processing.

Graphene can be produced in solution by liquid phase exfoliating graphite (or graphene powder) via ultrasonication (or shear mixing or microfluidic exfoliation) both in aqueous and/or organic solvents. Preferably, the carrier liquid is selected from one or more of water, ethanol, NMP, chloroform, benzene, toluene, di-chlorobenzene, iso-propyl alcohol, ethanol and/or other organic solvents. Sonication is generally then followed by sedimentation based ultracentrifugation to purify the dispersion. After removing solid powder, the supernatant is obtained as the graphene ink.

### Production of Ink Containing Graphene/GRM Materials

We prepare Graphene-Ethanol ink (Gr-Eth) by ultrasonicating (1 hr) 5 mg/ml graphene nanoplatelets (GR1, Cambridge Nanosystems, CNS) in Ethanol. These nanoplatelets are produced by cracking methane and carbon dioxide gases in an enhanced plasma torch. The dispersion is then ultracentrifuged (Beckman Coulter Proteomelab XL-A mounting a SW 32 Ti swinging bucket rotor) at 10 k rpm for 1 hour and the top 70% is collected for the Gr-Eth and further characterization.

Three additional graphene inks were made. The first ink (Gr-Eth-HC) involved adding 10 mg/ml of graphene nanoplatelets (GR1, Cambridge Nanosystems, CNS) to Ethanol and was sonicated for 1 hour. No centrifugation was carried out on this ink. The second ink (Gr-DiW) involved ultrasonicating (Fisherbrand FB15069, Max power 800 W) natural graphite flakes (12 mg/ml) for 9 hours in deionized water with sodium deoxycholate (SDC, 9 mg/ml). The third ink (Gr-NMP) involved ultrasonicating natural graphite flakes (12 mg/ml) in N-Methyl-2-pyrrolidone (NMP) for 9 hours. The last two graphite dispersions are then ultracentrifuged (Sorvall WX100 mounting a TH-641 swinging bucket rotor) at 1 k rpm for 1 hour to remove thick (>10 nm) graphite flakes. The sediment is discarded while the top 70% of ink is re-centrifuged at 32 k rpm for 1 hour. The sediment is collected and it is re-dispersed in the solvent which was used to make the original dispersion. High concentration inks (10 mg/ml) can be made in this fashion.

Other methods for obtaining suitable graphene or GRM inks are outlined in WO2014/064432.

For inks intended for use in inkjet printing, nanoparticles in the ink should be smaller than the inkjet printing nozzle diameter. Typically, it is preferable that the nanoparticles are of the order of 50 times smaller than the nozzle size in order to reduce or avoid printing instability due to clustering of the particles at the nozzle edge which may cause deviation of drop trajectory, or agglomerates, which can cause unwanted blockages of the nozzle.

### Characterisation of Inks and GRM Materials

### Rheological Characterisation of Inks:

The surface tension may be measured using the pendant drop method (First Ten Angstroms FTA1000B). The shape of the drop suspended from a needle results from the relationship between the surface tension and gravity. The surface tension is then calculated from the shadow image of a pendant drop using drop shape analysis. A parallel plate rotational rheometer (DHR rheometer TA instruments (Gr-NMP and Gr-SDC inks) and Bohlin C-VOR Rheometer (Gr-Eth ink)) is used to evaluate the viscosity as a function of shear rate, the infinite-rate viscosity is found for the Gr-Eth, Gr-NMP and Gr-SDC inks. Ink density is evaluated from a (Sartorius ME5) microbalance where the density if the mass per unit volume (p=m/V). The viscosity is found to be the similar for each ink.

Rheological measurement of the inks may be beneficial, as rheology of the ink can determine the reliability of drop jetting during inkjet printing.

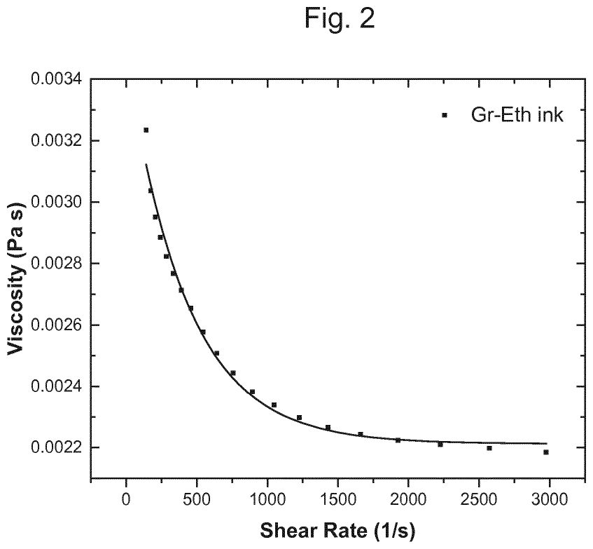

FIG. 2 shows a graph of viscosity (Pa s) against shear rate (l/s) for a Graphene-Ethanol ink.

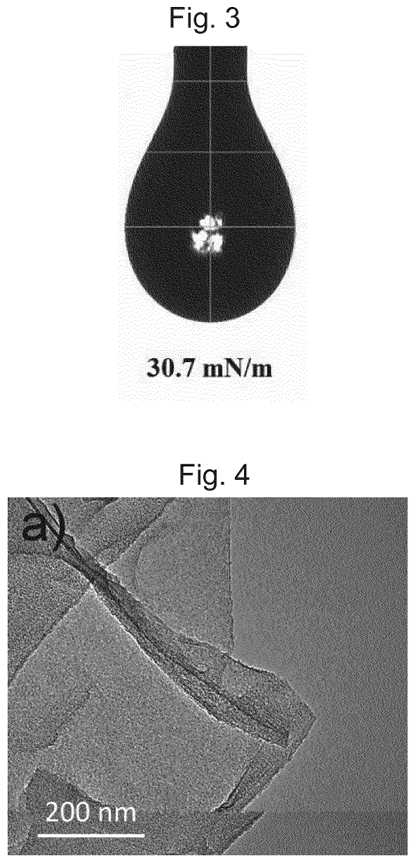

FIG. 3 shows a surface tension measurement using the pendant drop method as discussed above.

We derive viscosity (η), surface energy (γ) and density (ρ) as described above and estimate ηGr-Eth ˜2.2 mPa s (FIG. 2) and γGr-Eth ˜30.7 mN/m (FIG. 3) and ρGr-Eth ˜0.98 g cm⁻³, ηGr-NMP ˜1 mPa s and γGr-Eth ˜40 mN/m and ρGr-NMP ˜1 g cm⁻³, ηGr-SDC ˜1 mPa s and γGr-SDC ˜50 mN/m and ρGr-SDC ˜1 g cm⁻³.

### Transmission Electron Microscopy:

Drops of inks are dispensed on holey carbon transmission electron microscopy (TEM) grids for high resolution transmission electron microscopy (HRTEM) analysis, using a Tecnai T20 high-resolution electron microscope with an acceleration voltage of 200 kV operating in Bright Field mode.

FIG. 4 shows HRTEM micrograph of a single-layer graphene (SLG) flake and a few layers graphene flake from the Graphene-Ethanol (Gr-Eth) ink. HRTEM statistics reveal that such a sample typically consists of ˜12% single-, ˜30% bi-, and ˜58% multi-layer graphene flakes with ˜1 μm average size.

### Atomic Force Microscopy:

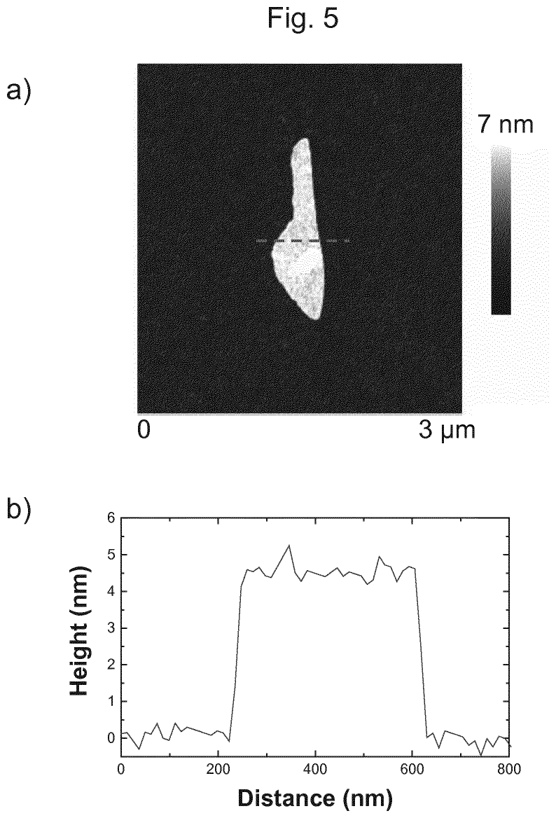

A Bruker Dimension Icon working in peakforce mode was used. For the characterisation of graphene powder, the sample was dispersed in ethanol and bath sonicated for 1 h. The dispersion was then centrifuged for 1 h at 10 krpm and the supernatant was collected, diluted 20 times in ethanol and 4 samples were drop casted on pre-cleaned Si/SiO2 substrates. Each sample was scanned across 3 different areas. Resulting AFM topographical and profile images can be seen in FIG. 5. FIG. 5 shows (a) an Atomic force microscopy (AFM) topographic image of typical nanoplatelets in the Gr-Eth dispersion; and (b) a corresponding cross-sectional profile taken along the dashed line of FIG. 5(a).

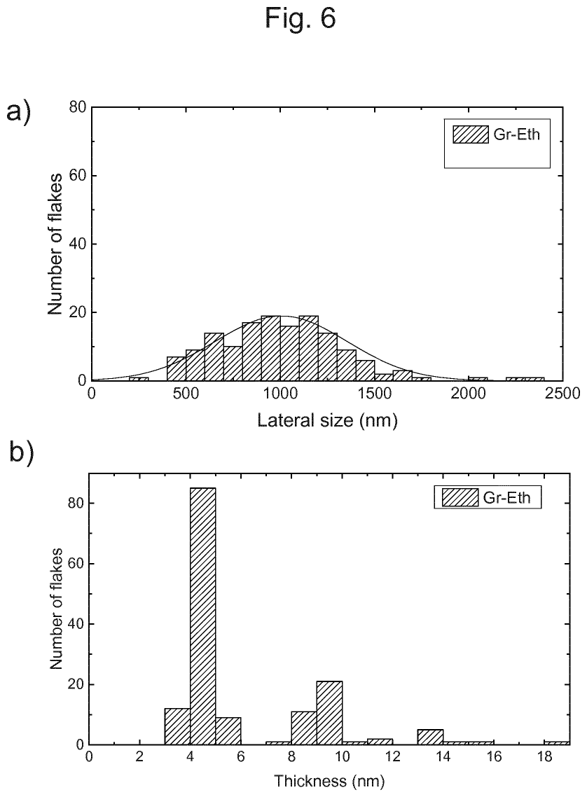

FIG. 6 shows (a) the flake lateral size distribution and (b) the apparent thickness for this Gr-Eth ink dispersion. This data is based on a sample size of 150 flakes/nanoplatelets. The AFM statistics on the lateral flake size show a Gaussian distribution for Gr-Eth ink flakes with a mean flake size of 1.04 μm. Furthermore ˜57% of the flakes in the Gr-Eth ink have a thickness of 4-5 nm. There is also a smaller population of flakes (˜20%) with a higher thickness of ˜9 nm.

### Optical Absorption Spectroscopy:

Optical absorption spectroscopy (OAS) is used to estimate the concentration of the ink via the Beer-Lambert law according to the relation A=α cl, where A is the absorbance, l [m] is the light path length, c [g/L] is the concentration of dispersed graphitic material, and α [Lg⁻¹ m⁻¹] is the absorption coefficient.

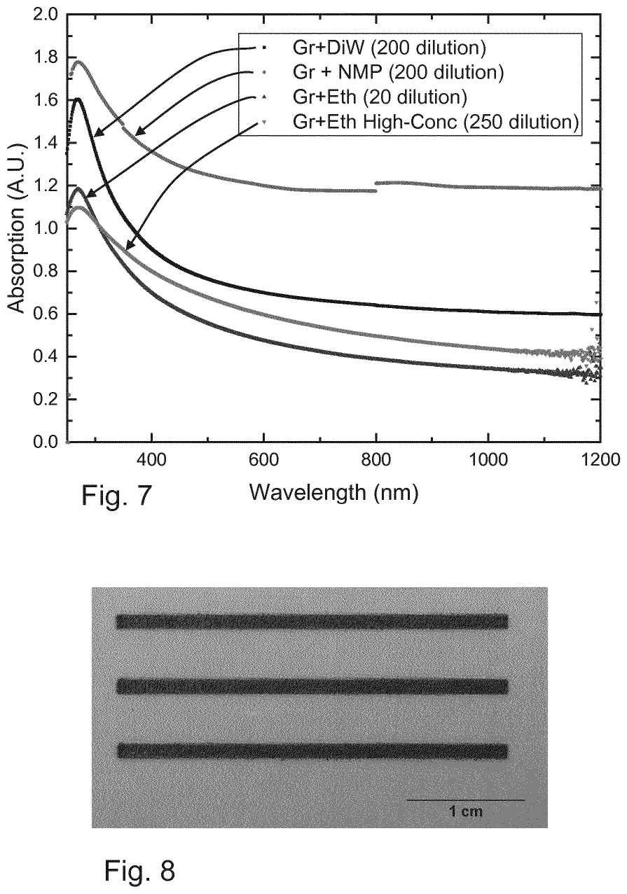

FIG. 7 plots an OAS spectra (Aglient Cary 7000 UMS) of Gr-Eth inks diluted to a 1:20 ratio, to avoid possible scattering losses at higher concentrations. The spectra for the Gr-Eth ink is consistent with reported OAS spectra for graphene inks, showing the peak at in the UV region attributed to the exciton-shifted van Hove singularity in the graphene density of states. Using α ˜2460 Lg⁻¹ m⁻¹ at 660 nm for the ink, we obtain a concentration of cGr-Eth ˜0.36 mg/ml.

FIG. 7 also shows OAS spectra for the Gr-DiW, G-NMP and Gr-Eth-HC inks. Graphene concentrations are estimated (via Beer-Lambert law) to be 9.7, 9.6 and 10 mg/mL respectively.

### Modification of GRM Inks

Printable GRM inks could be chemically modified/functionalised to be positively or negatively charged by the use of chemical oxidation/reduction steps or functionalization by molecules with charged chemical bonds. For example positively charged graphene oxide (GO) ink can be synthesized by adding DDAB (30 mg) into a GO solution (10 mg/10 mL) in acidic surrounding followed by sonication.

### Methods for Characterisation of Flexible Electronic Components or Devices

A range of methods used for characterisation of the flexible components or devices are set out below.

### Washability Test:

The conductive graphene fabrics are washed with water containing soap and sodium carbonate. Copper tape is added to the edges of the fabric where necessary in order to preserve the position of the electrical contacts on the fabric.

### Atomic Force Microscopy Scratch Test:

A Rockwell indenter (100 μm) is used to apply a normal force to the sample from an initial load of 0.03N to 0.5N at a loading rate of 0.10 N/min while the friction force, acoustic emission (AE) was recorded. The cantilever is moved across the sample at a speed of 0.64 mm/min.

### Raman Spectroscopy:

Raman measurements are collected with a Reinshaw 1000 InVia micro-Raman spectrometer at 514.5 nm and a ×50 objective, with an incident power of ˜0.3 mW.

### Tensile Testing:

The sample stripes or bundles can be placed between the machine grippers and a strain of 0.3 N/m\hat{ }2 is applied and stress measured until fracture.

### Electrical Resistance Measurement:

The electrical resistance of printed 1 mm wide films was characterised using a 2-point probe across a distance of 1 cm.

### Sheet Resistance Measurement:

Sheet resistance of dip-coated samples may be measured using a 4-point probe and reading off a Keithley meter

### Scanning Electron Microscopy:

SEM imaging may be used to image the surface morphology of the fabric substrate, before and/or after deposition of a GRM nanoplatelet layer.

### Example 1: Inkjet Printed Electronic Components Using Gr-Eth Ink

The inkjet printed circuits were prepared using a (Fujifilm Dimatix, DMP-2800) inkjet printer. Firstly a cartridge (Fujifilm DMC 11610) was filled with the prepared Gr-Eth ink and was deposited at an inter-drop spacing (i.e the centre to centre distance between two adjacent deposited droplets) of 25 μm onto cotton fabric coated with 1 layer of polyurethane. Once a droplet gets ejected it falls under the action of gravity until it contacts the substrate and spreads according to Young's equation, γ_{SV}−γ_{SL}−γ_{LV} cos θ_{c}=0, (where γ_{SV} [mJ m⁻²] is the solid-vapour surface energy, γ_{SL} the solid-liquid interfacial tension, and γ_{LV} the liquid-vapour surface tension). The drop then dries through solvent evaporation (the platen was kept 60° C. throughout printing) and the resulting thickness depends on the number of droplets delivered per unit area, the drop volume and the concentration of nanoplatelet material in the ink. Consequently a stripe of graphene ink is printed to our desired pattern as shown in FIG. 8. The printed interconnection is flexible, and may be bent without breakage.

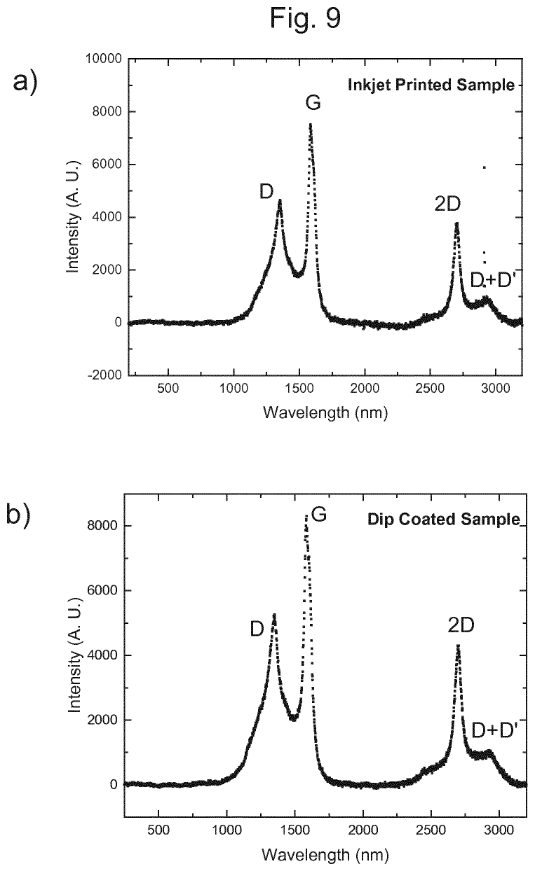

Raman spectroscopy (see methods) was undertaken on the printed conductive strip. The resulting Raman spectrum for this Example is shown in FIG. 9 (a). The spectrum displays presence of the D and D′ peaks, the G and 2D peaks, as well as the combination mode D+D′ peak. The G peak at ˜1580 cm⁻¹ corresponds to the E_{2g} phonon at the Brillouin zone (BZ) center. The D peak is due to the breathing modes of sp2 rings and requires a defect for its activation by double resonance (DR). The 2D peak is the second order of the D peak and can be always seen, even when no D peak is present, since the activation of two phonons with the same momentum, one backscattering from the other, does not require defects and irregular edges. Double resonance intra-valley process gives rise to the D′ peak. The 2D′ is the second order of the D′, while the D+D′ corresponds to the combination of D and D′ phonons but it has no back scattering restriction in double resonance unlike the D and D′ peaks. In previous work, the inventors have found that the ratio of intensity ratio of the D and G peaks, I_{(D)}/I_{(G)}, as a function of the full width at half maximum of the G-peak, (FWHM_{(G)}) allows us to discriminate between disorder localized at the edges and disorder in the bulk of the samples. This is mostly attributed to the edges of submicrometer flakes, rather than to a large amount of structural defects within the flake [Casiraghi Nano Lett 2009]. This observation is was also supported by the low Disp_{(G)}<0.09 cm−1/nm, which is lower than what would typically be expected for disordered carbon.

The electrical resistance of the printed 1 mm wide films was characterised using a 2-point probe across a distance of 1 cm where it was found that the films reached percolation after 30 layers (i.e. printing passes) as shown in Table 1. As the number of the ink-jet printing layer increases, more and more flakes are deposited onto the surface. As a result, a stripe with flakes is gradually formed. Once the flakes connect with each other, the film becomes conductive.

TABLE 1
Resistance of the ink-jet printed wires with different printing layers

| Layer | Resistance/MΩ |
|---|---|
| 30 | 4.81 |
| 60 | 1.16 |
| 90 | 4.17 |
| 120 | 1.51 |

### Reference Example 2: Dip-Coated e-Textiles

Electrically conducting e-fabrics were fabricated by dip-coating of fabric (poplin 100% cotton) into graphene ink directly. No smoothing layer was used. Dip coating allows the ink to infiltrate deeper into the fabric than comparative surface coating techniques may allow. The cotton fabric first undergoes a chemical functionalization treatment as described in the method section above, in order to cationize the fabric before application of the ink. Some fabric samples do not undergo chemical modification, to provide comparative samples. The fabric samples are then respectively dip-coated into one of three respective inks: Gr-Eth-HC, Gr-DiW, and Gr-NMP, the formulation of each of which is discussed above.

Two types of cotton fabric were used in the following coating process, type 1 is a dense cotton fabric (7.4 tex) while type 2 (13.8 tex) has less threads of fibers per unit area. Modified and control cotton fabrics are then dipped into 20 mL of graphene ink of choice, the immersed fabric is then removed and dried at room conditions (21° C.) overnight. After drying the fabric is turned over and once again immersed in the ink and left to dry once more. The resulting fabrics are labeled the Gr-NMP-F, Gr-DiW-F and Gr-Eth-HC-F depending on the graphene ink which was used as a coating. In order to identify the most effective chemical functionalization treatment the Gr-Eth-HC ink was applied to fabric modified with three different cations: 3-chloro-2-hydroxypropyltrimethylammonium chloride, bis-quaternary ammonium salt and polymerizable bis-quaternary ammonium salt. These samples were be labeled Gr-Eth-HC-F-1 to Gr-Eth-HC-F-8 indicating the sample number.

TABLE 2
Samples tested

| | Textile | |
|---|---|---|
| Sample | Type | Modification |
| Gr-Eth-HC-F-1 | Type 1 | 3-chloro-2-hydroxypropyltrimethylammonium |
| | | chloride |
| Gr-Eth-HC-F-2 | Type 2 | 3-chloro-2-hydroxypropyltrimethylammonium |
| | | chloride |
| Gr-Eth-HC-F-3 | Type 1 | bis-quaternary ammonium salt |
| Gr-Eth-HC-F-4 | Type 2 | bis-quaternary ammonium salt |
| Gr-Eth-HC-F-5 | Type 1 | polymerizable bis-quaternary ammonium salt |
| Gr-Eth-HC-F-6 | Type 2 | polymerizable bis-quaternary ammonium salt |
| Gr-Eth-HC-F-7 | Type 1 | None |
| Gr-Eth-HC-F-8 | Type 2 | None |
| Gr-DiW-F | Type 2 | None |
| Gr-NMP-F | Type 2 | None |

The resulting dip-coated fabric samples (Gr-Eth-HC-F-1 to Gr-Eth-HC-F-8) are characterized by Raman spectroscopy as shown in FIG. 9 (b), this being a representative Raman result for one such sample. Methods and analysis of the Raman spectroscopy are discussed above, however it is noted that the graphene found in the dip-coated samples has a similar fingerprint to the Raman fingerprint of the inkjet printed samples on planarised cotton fabric (i.e. fabric having a smoothing layer applied) as shown in FIG. 9 (a). It can be concluded that the deposited graphene in both of these Examples is therefore of similar quality.

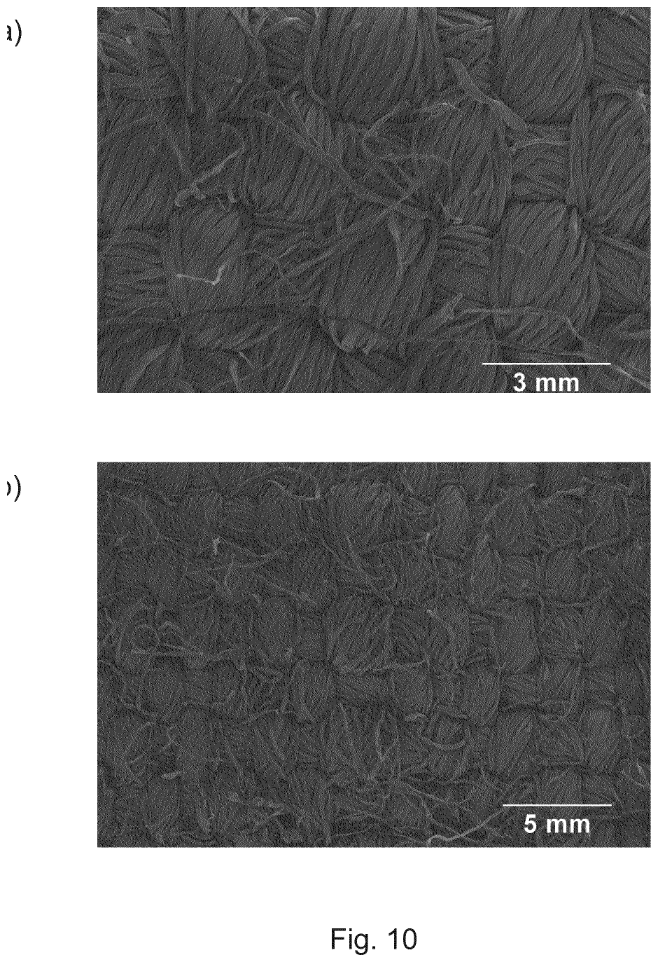

The Gr-Eth-HC-F-8 sample was also characterized with scanning electron microscopy both before (FIG. 10 (a)) and after (FIG. 10 (b)) dip-coating of the sample. It can be seen from the SEM images that the coating process helps to fill in voids and roughness of the fabric.

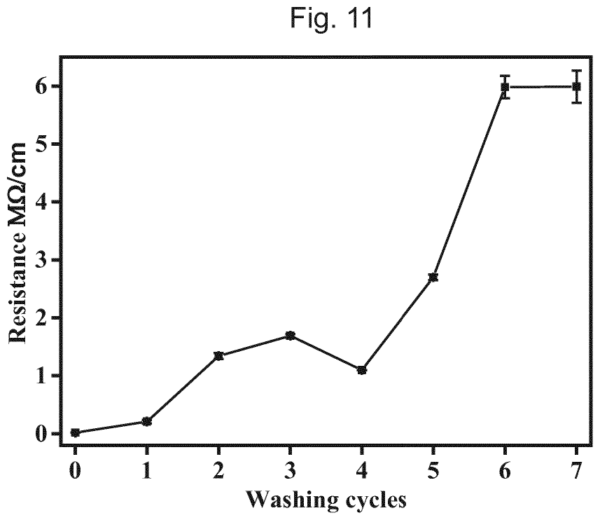

The fabric electrical resistance of the samples was then measured using a 2-point probe across a distance of 1 cm, using 1 cm² pieces of cloth. Silver paint (agar scientific) was used to paint on contacts. The fabrics had an electrical resistance of 0.43±0.35 kΩ, 18±4 kΩ and 51±18 kΩ for the Gr-NMP-F, Gr-DiW-F and Gr-Eth-HC-F fabrics respectively. The washability of these fabrics was then tested by covering both side contacts of the samples with copper tape to avoid damage, and implementing the fabric washing process (see methods). A layer of polyurethane protective coating is laminated on top of the graphene-coated fabric, while uncoated graphene-fabrics also undergo the same treatment as control samples. FIG. 11 shows the sheet resistance of Gr-Eth-HC samples without a polyurethane coating as a function of washing cycle. The resistance increases from 12 kΩ/cm to 6 MΩ/cm as a function of the washing cycles. This is an indication that the graphene layers suffer degradation due to partial wash-off of the layers as the number of washing cycles increase. On the other side when polyurethane overlayer is applied the resistance shows a small variation that is considered within the 7% measurement error.

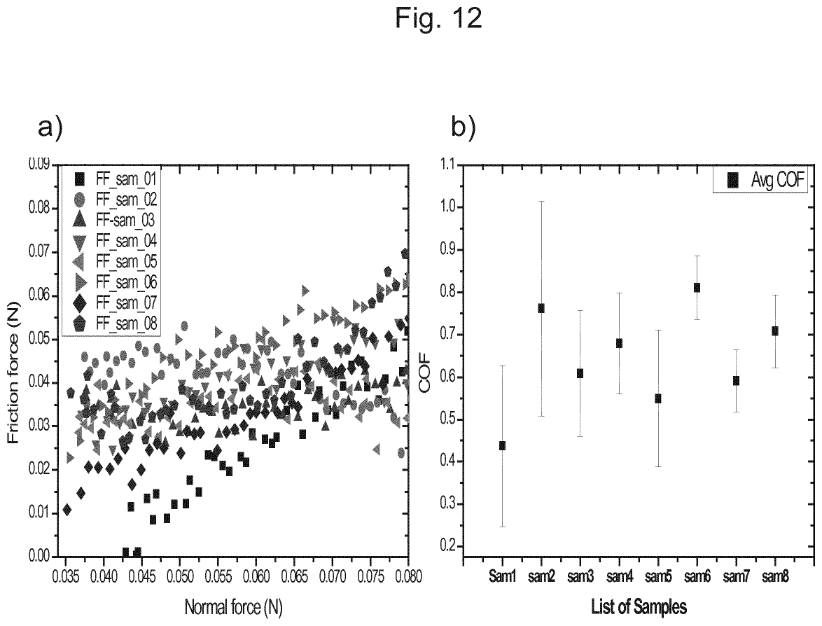

In order to investigate the effect of different types of chemical modification on the fabric samples, the samples were subjected to a number of mechanical tests. Scratch tests with an atomic force microscope (AFM) were undertaken (see methods) on the samples in order to determine the extent of the graphene adhesion to the fabrics. The investigation assumes that the same cotton fibre has been used (i.e of equal linear density) and that only the coating chemistry has been varied. Furthermore it is assumed that the thickness of the coatings of the different samples are in close precision to one other. As shown in FIG. 12 (a) a normal force was applied from 0.03 N to 0.5 N on all samples and frictional force and acoustic emission (AE) was recorded. FIG. 12(a) shows only the applied force range up to 0.08N, for clarity. The coefficient of friction (COF) was measured as the ratio of friction force and applied normal force, and is displayed in FIG. 12 (b). The frictional force increases with increasing normal force which is the resistance that is offered by sample to counter tip motion. From FIG. 12(b) we find that the decreasing coefficient of friction is as follows FF_{sam_6}>FF_{sam_2}>FF_{sam_4}>FF_{sam_5}>FF_{sam_8}>FF_{sam_3}>FF_{sam_7}>FF_{sam_1}. The designation FF_{sam_6}, for example, refers to sample 6 identified above, i.e. Gr-Eth-HC-F-6.

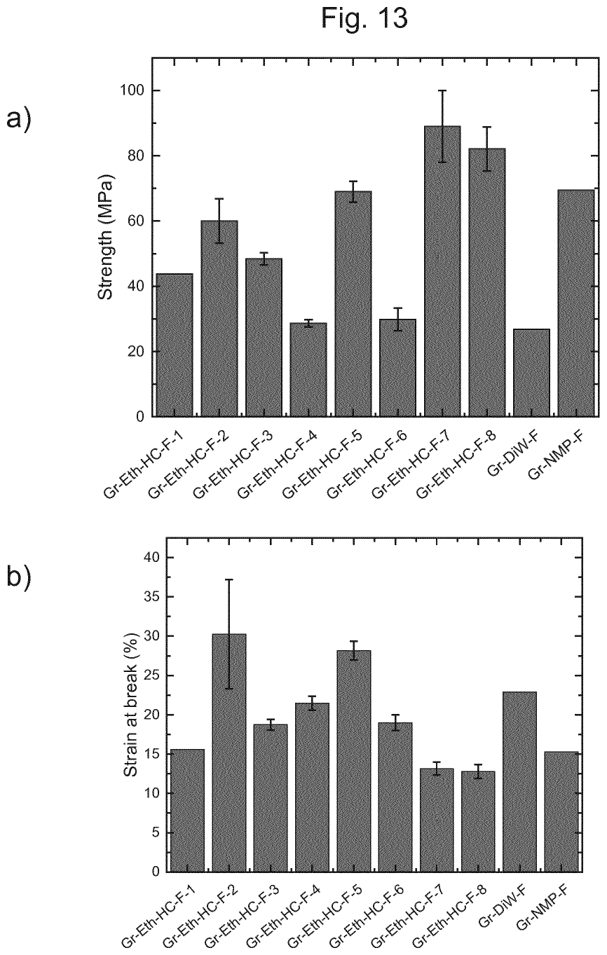

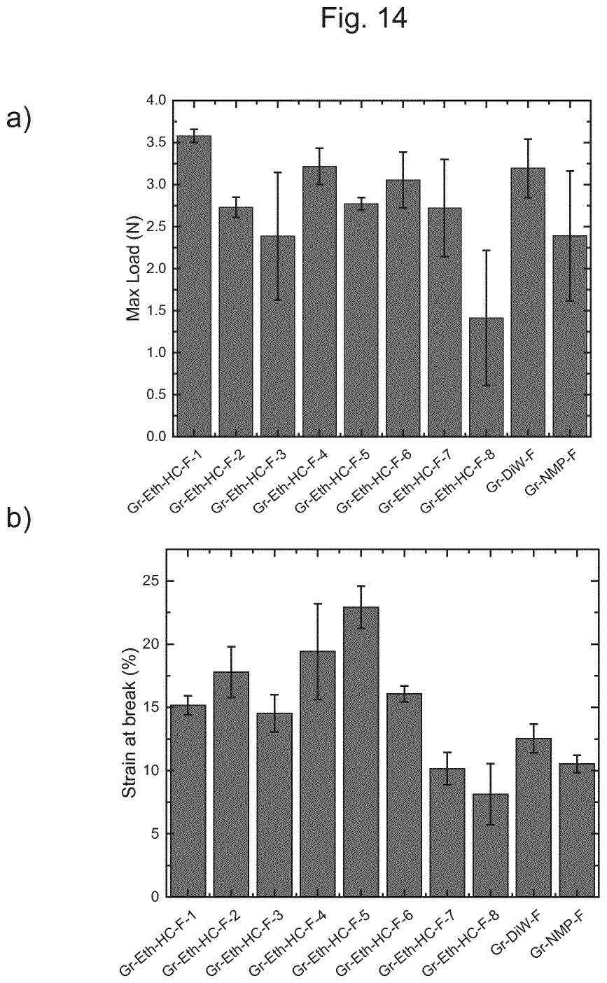

The fabrics were also subjected to tensile testing (see methods), the dip coated samples were tested as strips (cutting rectangular parts of the dip coated samples) and also as bundles (i.e a collection of fibrils taken from each of the fabric samples). From FIGS. 13 and 14 it is clear that the chemical modification affects the mechanical properties of the fabrics and the fibers themselves. FIG. 13 shows (a) strength (MPa) and (b) Strain at break for each sample listed in Table 2. FIG. 14 shows (a) Max load (N) for each bundle of fabric sample fibres and (b) Strain at break for each bundle of fabric sample fibres.

We can see from the above figures that the strain to break of the bundles is higher (about 5%) as a consequence of the modification while the strength of the fibers remains approximately consistent. Without wishing to be bound by theory, the inventors speculate that this could be due to the increased graphene pickup as a result of the fabric cationization. The fabrics are induced with a positive charge due to the cationization while the negatively charged OH groups on the edges of the graphene flakes result in a net attraction between the two materials resulting in an increase in pickup.

At the time of writing, it is considered that dip-coating is a less preferred approach to the formation of the embodiments of the invention, compared for example with inkjet printing. One reason for this is that inkjet printing can be carried out at high resolution, forming the material layers in a desired pattern in one process. Another reason for this is that inkjet deposition appears to form superior quality layers of deposited GRM material.

### Reference Example 3: GRM-Based Printed Photodetectors

Two inks were manufactured. The first was a graphene ink, the second was a MoS₂ ink. Each used a particle size of <30 microns mixed at a concentration >50 g/L with sodium deoxycholate surfactant (SDC) at a concentration 9 g/L in water and stir bar mixed for 5 min. Then each dispersion was exfoliated by high shear mixer for 1 hour. The final product of the exfoliated material was collected. Cellulose (CMC) was continuously added whilst stirring to adjust the viscosity to the required value. CMC was slowly added until fully dissolved.

The textile fibre was chemically modified as follows. After washing with deionized water, the fabrics were cationized using the exhaust method at room temperature in a weight ratio of 17:1. The cationization was performed with CHPTAC concentration 35 g/L. A 60 g fabric sample was first immersed in the solution of CHPTAC. Following this, NaOH was added to the solution to achieve a CHPTAC/NaOH ratio of 2.33. The fabric was gently stirred and left for 20 min, then removed and hand squeezed to remove excess water. The wet pick-up was approximately 100%. The treated fabric was then placed in a plastic bag to prevent chemical migration and water evaporation and stored at room temperature for approximately 24 h. After rinsing 5 times with tap water, the treated fabric was immersed in an acetic acid solution (1 g/L) for 3-5 min to neutralize the alkalinity.

Graphene ink was flexographically printed (or printed with any other suitable printing/coating technique as described previously) to deposit a thin film, of thickness approximately 500 nm, acting as electrode on the functionalised textile. Subsequently a MoS₂ ink was flexographically printed to produce an equally-thick MoS₂ film. A graphene film was flexographically printed on the top of the stack.

The graphene-MoS₂-graphene heterostructure was protected by applying a protective polymer (e.g. polyurethane) coating on top of the conductive graphene interconnection, generally by bar-coating or screen printing. This heterostructure device represents a wearable and washable GRM-printed photodetector on textiles.

### Manufacture and Characterization of Further Electronic Devices

In this part of the disclosure, we demonstrate the fabrication of flexible and washable fully inkjet printed graphene/hexagonal-boron nitride field effect transistors (FETs) on polyethylene terephthalate (PET) film and on polyester fabric. The devices have a charge carrier mobility of as high as μₕ=150±18 cm² V⁻¹ s⁻¹ on polyethylene terephthalate (PET) film and μₑ=73±23 cm² V⁻¹ s⁻¹ on polyester fabric, at low operating voltages (<5 V). In the preferred embodiment described here, the FET is fabricated by inkjet printing heterostructures of graphene and h-BN inks prepared by scalable liquid phase exfoliation and microfludization production techniques, respectively. The devices remained operational and maintained their performance even under strain of bending radius 4 mm. The printed FETs show stable operation for periods up to 2 years, indicating the two-fold role of the h-BN layer as a dielectric and encapsulant. Finally, we demonstrated that the hexagonal-boron nitride textile FETs are washable up to 20 cycles using an encapsulation layer (formed in this embodiment from polyurethane) which is ideal for applications in wearable and textile electronics. The FET is sometimes referred to here as a thin film transistor (TFT).

### Abbreviations

### 2D—Two-dimensional

FET—Field effect transistor
TFT—Thin film transistor
h-BN—Hexagonal Boron Nitride

### PET—Polyethylene Terephthalate

### LPE—Liquid Phase Exfoliation

### OLED—Organic Light-Emitting Diodes

NMP—N-Methyl-2-pyrrolidone
CMC—Carboxymethylcellulose sodium salt
SEM—Scanning electron microscopy
EDX—Energy-dispersive X-ray spectroscopy
rGO—Reduced graphene oxide
CNT—Carbon nanotube
PVA—poly(vinyl alcohol)

### PDMS—Polydimethylsiloxane

PEDOT: PSS—poly(3,4-ethylenedioxythiophene) polystyrene sulfonate
SAA—Sodium alga acid
PQAS—Polyurethane, Polymerizable quaternary ammonium salt

### HRTEM—High-resolution Transmission Electron Microscopy

### TEM—Transmission Electron Microscopy

HAADF-STEM—High angle annular dark field scanning transmission electron microscopy
NMF—Non-negative matrix factorization

### FIB—Focused Ion Beam

### Further Background

Metal oxide semiconductor technology has dominated the electronics industry for the last century, however this technology is incompatible with printed electronics due to poor tensile performance metals and metal oxides have with flexible substrate materials such as polymers and textiles [De and Coleman (2011)]. The discovery and development of electrically conductive organic polymers Hideki et al (1977); Heeger (2001)] advanced the field of printed electronics allowing the manufacture of flexible devices with solution processibility, enabling large scale manufacture [Sirringhaus et al (2000)]. However both metal oxides and organic polymers have low charge mobility (μ) (˜0.01-10 cm²/Vs), which has limited their prospects in specific applications such as RFID tags and control electronics for displays [Nathan et al (2012)]. The exfoliation of graphene [Novoselov et al (2005), (2005) and (2004)] has driven a surge of exploration of novel two-dimensional (2D) materials with unique properties [Geim and Grigorieva (2013); Ferrari et al (2014)]. Graphene has shown great potential in the field of printed electronics owing to its mechanical flexibility [Gomez De Arco et al (2010)], stretchability [Lee et al (2008)], thermal conductivity [Yao et al (2016)], high electrical conductivity [Novoselov (2005)], environmental stability [Liu et al (2015)] and compatibility with low cost large scale manufacturing [Paton et al (2014)]. Moreover solution processed graphene field effect transistors (FETs) can have a high carrier mobility (about 100 cm²/Vs) [Torrisi et al (2012)] coupled with an ambipolar behaviour which make it an attractive material for radio frequency applications [Akinwande (2014)].

Atomically thin 2D materials, identified by their intralayer covalent bonding and interlayer van der Waals bonding, such as graphene [Novoselov et al (2005), (2005) and (2004)] and boron nitride (BN) [Novoselov et al (2005); Geim and Grigorieva (2013)], can be arranged into heterostructures, thus creating structures with novel properties which are different from those of the individual components [Novoselov (2011)]. The combination of conducting, insulating and semiconducting 2D materials in different combinations allows for a practically infinite number of different heterostructures with precisely tailored properties with multiple functionalities and improved performance for novel applications [Novoselov (2011); Wither et al (2015)]. These 2D materials can be exfoliated in solution by liquid phase exfoliation (LPE) or microfluidization and developed into inks [Nicolosi et al (2013); Lotya et al (2009); Hernandez (2008); Karagiannidis et al (2017)]. Consequently, layered structures of 2D material ink can then be printed in part or as whole by means of different printing technologies such as inkjet [Torrisi (2012); Kelly et al (2016)], spray [Kelly et al (2016)], screen {Gualandi (2016)], gravure [Lau et al (2013)] and flexographic printing [Yan et al (2009)]. These printed techniques offer a competitive advantage over conventional silicon based electronics as the high-vacuum equipment, subtractive processes and lithography add to the number of processing steps and the overall cost involved Baeg et al (2013)]. Thus, there have a myriad of printed electronics applications which been developed over the past two decades, such as organic light-emitting diodes (OLED) [Kopola et al (2009)], photovoltaic devices [Krebs et al (2009)] and transistors [Sirringhaus (2000)]. Perhaps even more interestingly is the adaptation of many printed devices for applications in wearable electronics such as thermoelectric power generators [Kim et al (2014)], sensors [Gualandi et al (2016)], RFID [Lakafosis et al (2010)], energy storage [Chen et al (2010)] and antennas [Chauraya et al (2013)] which enhance the users ease of integration with external electronics while providing analytical information to the wearer by monitoring functions such as movement [Ren et al (2017)].

In this disclosure inkjet printing is chosen to print FETs on polyethylene terephthalate (PET) and polyester as it is a non-contact, well controlled one step deposition and patterning of inks on any substrate and at room temperature, moreover it is a scalable technique amenable for mass production [Krebs review article (2009)]. Inkjet printing also offers reduced material wastage when compared to other printing due to the small amount of material it uses (typically about 3 ml) and has excellent control over the deposition of ink which can be used to create very complex patterns with high resolution (about 20 μm) [Krebs review article (2009)]. Graphene and BN inks are formulated though LPE and microfluidization respectively and are subsequently inkjet printed with a commercially available silver and PEDOT: PSS inks to fabricate FET heterostructures in arrays at room temperature and ambient pressure. The devices achieved an exceptionally high mobility up to 150 cm²/Vs on PET and up to 73 cm²/Vs on polyester fabric which was coated with a polyurethane planarization layer. The flexibility and washability of the devices was also examined to establish their applicability in real world applications.

### Results and Discussion

### Ink Formulation:

In this study we used a drop-on-demand ink jet printer (Fujifilm Dimatix DMP-2800). The viscosity, η[mPa s], surface tension, γ[mN m⁻¹], density, ρ[g cm⁻³] and nozzle diameter, a [μm] influence the jetting of individual drops from a nozzle [Derby and Reis (2003)]. During droplet ejection a primary drop may be followed by secondary (satellite) droplets which need to be avoided during printing [Dong et al (2006); Jang et al (2009)]. The inverse Ohnesorge number is used as a figure of merit, Z=(γρa)^{1/2}/η and is commonly used to characterize the drop formation, stability and assess the jettability of an ink from a nozzle [Derby and Reis (2003); Dong et al (2006); Fromm (1984)]. A range of 2<Z<24 has been identified as an optimal range which minimizes the number of satellite droplets and improves stability [Torrisi et al (2012); Fromm (1984)]. Additionally, nozzle clogging can be an issue unless the particles have diameter of about 1/50 or less times the nozzle diameter [Torrisi et al (2012)]. Therefore we used a 21 μm diameter nozzle (Fujifilm DMC-11610) where the volume of individual droplets from this nozzle is about 10 μL. When inkjet printing, the ejected drop falls under the action of gravity until it contacts the substrate and spreads according to Young's equation, γ_{SV}−γ_{SL}−γ_{LV} cos θ_{c}=0, (where γ_{SV} is the solid-vapor surface energy, γ_{SL} the solid-liquid interfacial tension, and γ_{LV} the liquid-vapor surface tension) [Ryntz and Yaeneff (2003)]. The drop then dries through solvent evaporation (the platen was kept 20° C. throughout printing) and the resulting thickness will depend on the number of droplets delivered per unit area (controlled by the interdrop spacing, i.e the centre to centre distance between two adjacent deposited droplets), the drop volume and the concentration of material in the ink.

Suitable inkjet printable formulations which are produced by liquid phase exfoliation [Lotya et al (2009); Hernandez et al (2008)] typically contain surfactants or polymer stabilization agents which can act as a source of contamination which can hinder device performance however they can also positively impact the ink by acting as an adhesion or rheology modifier [Karagiannidis et al (2017)]. High boiling point solvents (>150° C.), such as N-Methyl-2-pyrrolidone (NMP) can stabilize 2D materials without stabilization agents due to a matching of the Hansen solubility parameters [Lotya et al (2009); Hernandez et al (2008); Hansen (2007)]. However, they are still far from ideal as they are based on toxic and expensive solvents which require high annealing temperatures (>150° C.) to remove residual solvent [McManus et al (2017)]. Low boiling point inks (<150° C.) are a suitable alternative, due to their fast evaporation at room temperature and have been reported though two solvent formulation where the mixture is tuned to improve the affinity of the solvent to the 2D crystals [Zhou et al (2011)]. However the different evaporation rate of the two solvents can result in rheological instabilities and particle aggregation over time. An alternative ink formulation route is though solvent exchange whereby 2D materials can be exfoliated effectively in a high boiling point solvent and subsequently transferred to a low boiling point solvent and concentration as desired [Zhang et al (2010)].

We prepare the 2D crystal-based inks are prepared as follows. The graphene ink is prepared by dispersing graphite flakes (10 mg/ml, Sigma-Aldrich No. 332461) and ultrasonicating (Fisherbrand FB15069, Max power 800 W) for 9 hours in NMP [Hernandez et al (2008)]. The graphene ink in NMP then undergoes a solvent exchange to ethanol (see methods, described below). The h-BN ink is prepared by mixing h-BN powder (10 mg/ml, Goodfellows <10 μm, B516011) with deionized water and carboxymethylcellulose sodium salt (CMC, Average Molecular Weight M_{W}=700,000, Aldrich No. 419338) (3 mg/ml), a biocompatible and biodegradable stabilization agent and rheology modifier [Karagiannidis et al (2017); Lin et al (2015)]. The h-BN/CMC mixture is then processed with a shear fluid processor, (i.e. a microfluidizer, M-110P, Microfluidics International Corporation, Westwood, Mass., USA) with a Z-type geometry interaction chamber with microchannels about 87 μm wide for 50 cycles, at 207 MPa system pressure and room temperature (20° C.) [Karagiannidis et al (2017)]. We use the microfluidic process to disperse and exfoliate h-BN while the high shear rate generated (about 9.2×10⁷ s⁻¹) helps to achieve high concentration dispersions [Karagiannidis et al (2017)]. The h-BN and graphene dispersions are then ultracentrifuged (Sorvall WX100 mounting a TH-641 swinging bucket rotor) at 3 k rpm (20 min) and 10 k rpm (1 hour) respectively to remove thick flakes which would clog printer nozzles. Subsequently, the supernatant (i.e top 70%) is decanted for further characterization. The rheological parameters (viscosity η, surface tension γ, density ρ) for both inks are determined as η_{BN} of about 1.7 mPa s, γ_{BN} of about 72 mN/m, ρ_{BN} of about 1.01 g cm⁻³; η_{GR} of about 1 mPa s, ρ_{GR} of about 30 mN/m, ρ_{GR} of about 0.82 g cm⁻³, consistent with previous reports [Torrisi et al (2012); Lotya et al (2009); Hernandez et al (2008)]. Consequently, we find a Z number for the h-BN (Z of about 19.4) and graphene (Z of about 22) inks, which are within the optimal Z range [Torrisi et al (2012); Fromm (1984)].

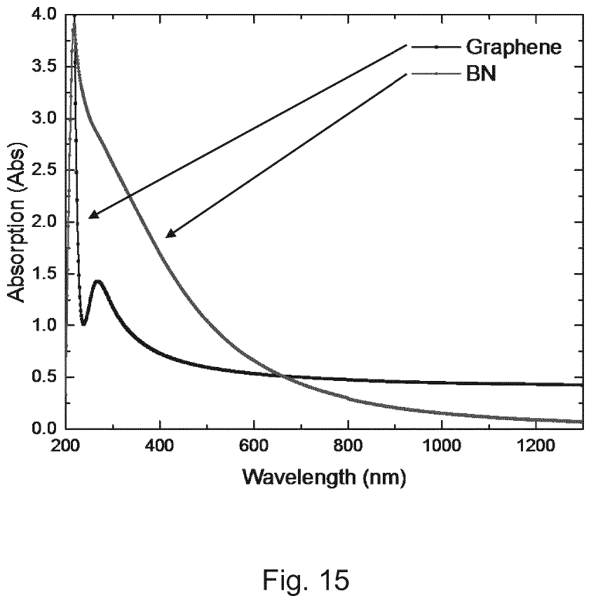

Optical absorption spectroscopy (OAS) can estimate the flake concentration [Lotya et al (2009); Hernandez et al (2008)] via the Beer-Lambert law which correlates the absorbance A=αcl, with the beam path length I [m] the concentration c [g/L] and the absorption coefficient α [L g⁻¹ m⁻¹]. FIG. 15 shows the absorption spectrum of h-BN (red) and graphene (black) inks diluted to 1:20 with water/CMC and ethanol respectively, to avoid possible scattering losses at higher concentrations. Using α_{BN} of about 2350 L g⁻¹ m⁻¹ for the h-BN ink [Nicolosi et al (2013); Shen et al (2015)] and α_{GR} of about 2460 L g⁻¹ m⁻¹ for the graphene ink [Hernandez et al (2008)] at 660 nm, we obtain c_{BN} of about 0.44 mg/ml and c_{GR} of about 0.42 mg/ml. The spectra for the graphene ink is mostly featureless due to the linear dispersion of the Dirac electrons [Mak et al (2008); Kravets et al (2010)] while the peak in the UV region is a signature of the van Hove singularity in the graphene density of states [Kravets et al (2010); Cheng et al (2013)]. The spectra for the h-BN ink has a peak located at 218 nm (λ_{g}, the optical band gap wavelength) which exponentially decays as the wavelength increases which is due to scattering [Shen et al (2015)]. The peak corresponds to an optical band gap E_{g} of 5.69 eV, where E_{g} is defined by hc/λ_{g} where h is the Planck constant, c is the speed of light in vacuum and A is the photon's wavelength [Chang et al (2013); Gao et al (20120); Sainsbury et al (2014)]. This value is consistent with previous reports for determination of the optical band gap for thin h-BN films [Gao et al (20120); Sainsbury et al (2014)].

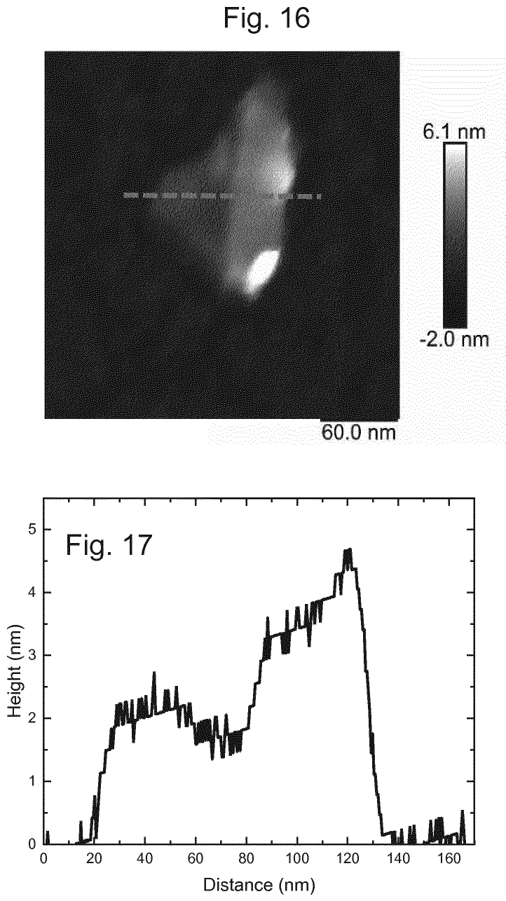

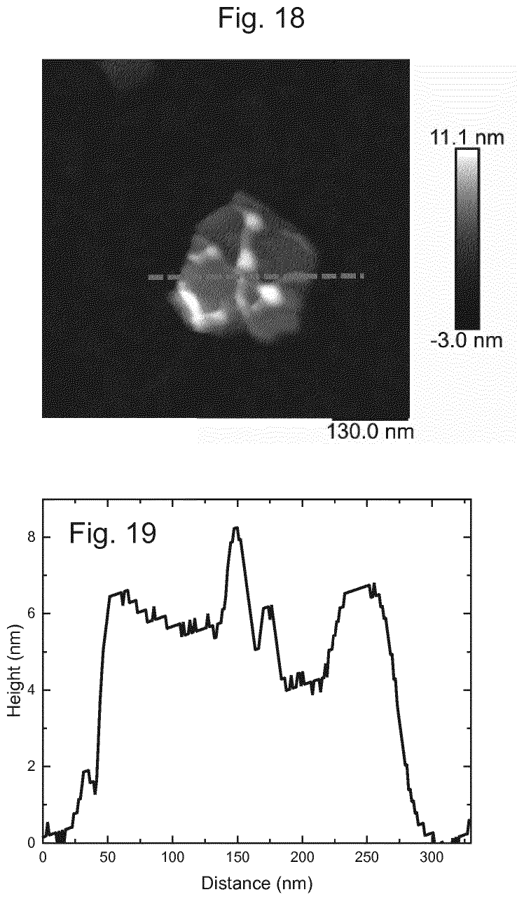

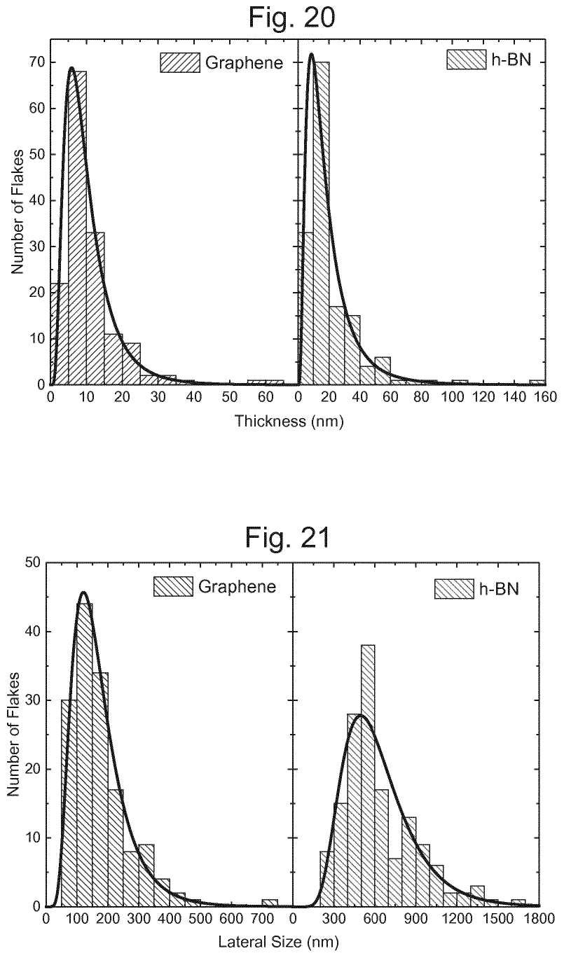

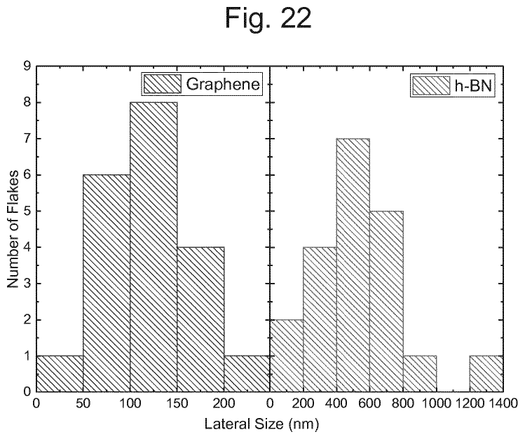

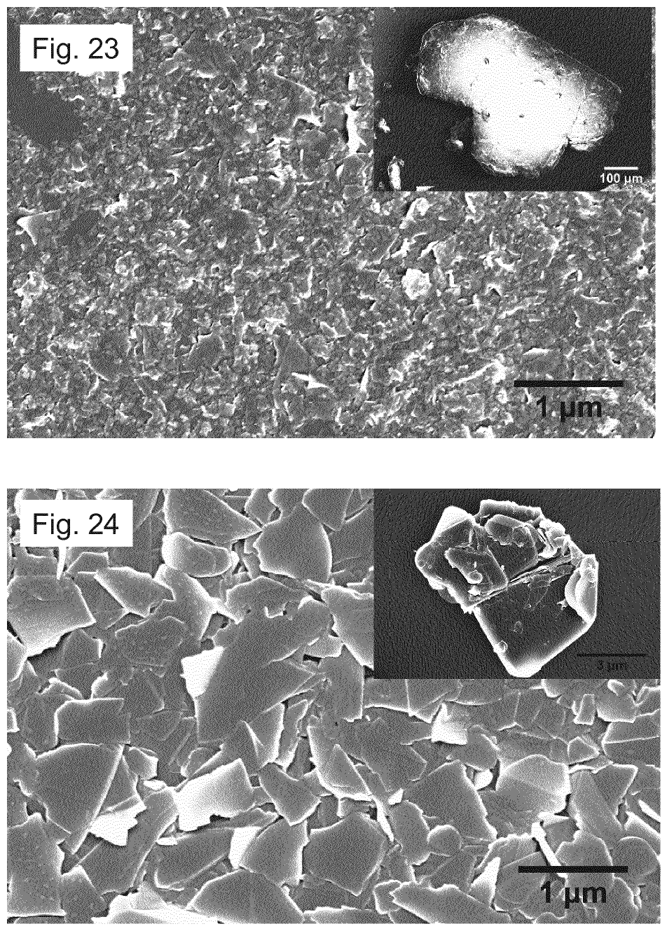

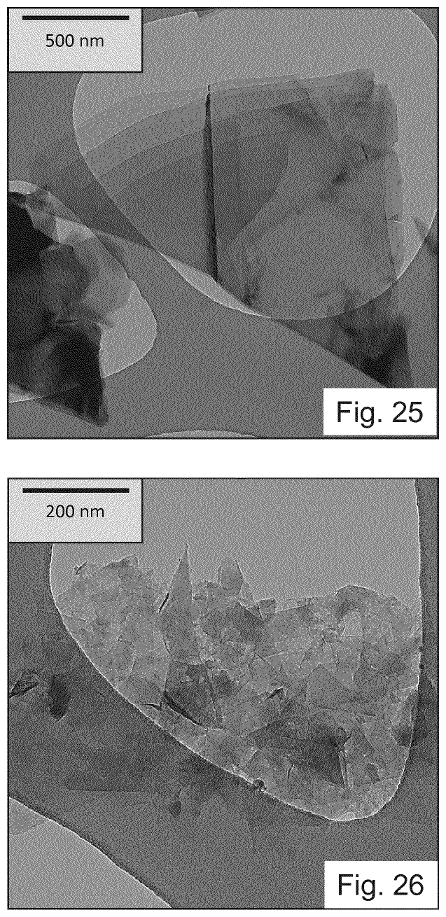

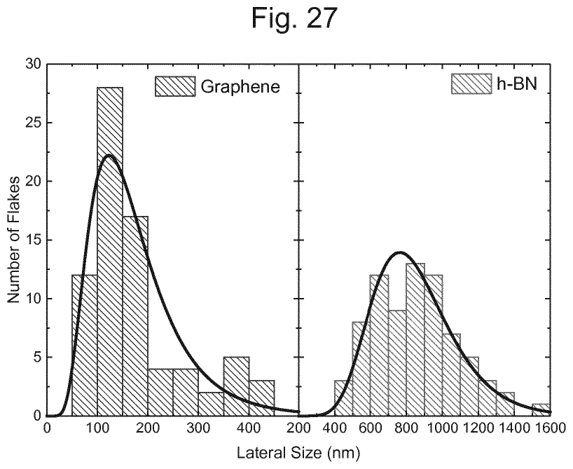

The average lateral size and thickness of the graphene and h-BN flakes are estimated by atomic force microscopy (AFM). FIGS. 16 and 18 show AFM micrographs of individual graphene and h-BN flakes of about 3 nm and about 5 nm thickness respectively, as confirmed by cross section profiles (FIGS. 17 and 19 respectively). FIG. 20 shows the statistics of the peak thicknesses extracted from AFM over 150 individual flakes of graphene and h-BN. The log normal distribution [Kouroupis-Agalou et al (2014)] is peaked at thicknesses of about 6 nm and about 9 nm for graphene and h-BN respectively, which indicates that these are few layer flakes. The lateral size distributions of each ink (FIG. 21), defined [Kouroupis-Agalou et al (2014)] as \sqrt{LW}, where L and W are the length and width of the flake are also investigated to make sure that this match with the inkjet jetability requirements. These also follow a log-normal distribution [Kouroupis-Agalou et al (2014)] which is peaked at 121 nm and 495 nm for graphene and h-BN flakes, respectively. Scanning electron microscopy (SEM) is used to assess the lateral size of the starting bulk material to that of the ink (FIG. 23 for graphene and FIG. 24 for h-BN). A statistical analysis of 20 flakes for the h-BN and graphene ink (FIG. 22), indicates a lateral size of 516±60 nm and 110±11 nm respectively verifying the AFM statistics. In each case we find that the lateral size of the bulk material decreases by an order of magnitude for the h-BN from about 5 μm and three orders of magnitude for the graphite about 400 μm, indicating the exfoliation of the bulk material into platelets. FIGS. 25 and 26 show high-resolution transmission electron microscopy (HRTEM) micrographs of a terraced h-BN flake and graphene flakes from the h-BN and graphene inks, respectively. The associated HRTEM statistics (FIG. 27) show a peak lateral size of about 760 nm and about 123 nm for the h-BN and graphene inks respectively which are in close proximity to the values obtained from AFM and SEM.

Inkjet Printed h-BN Capacitors:

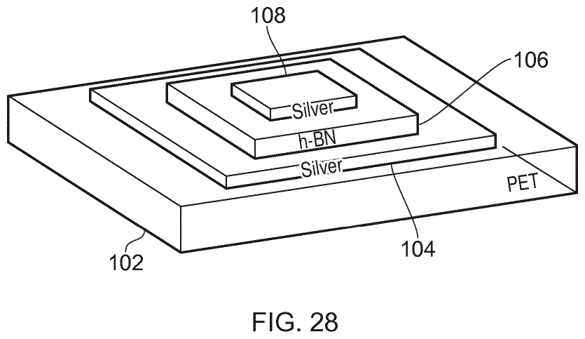

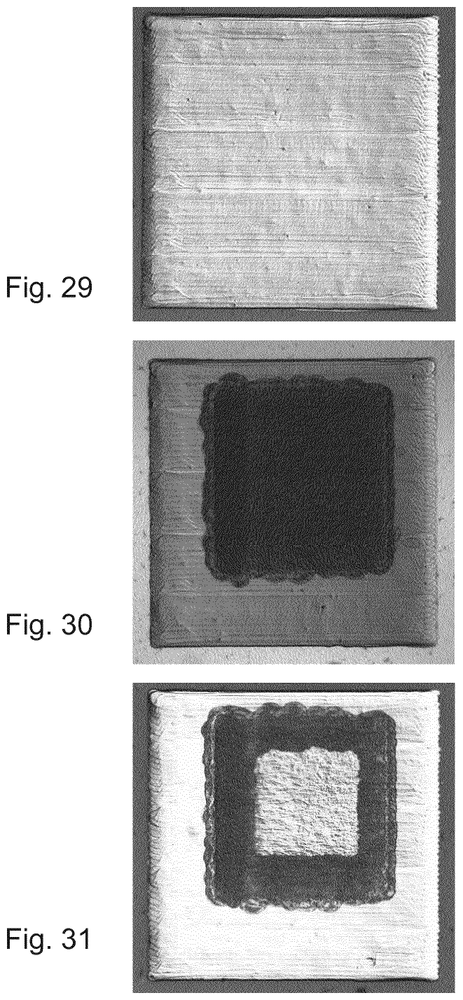

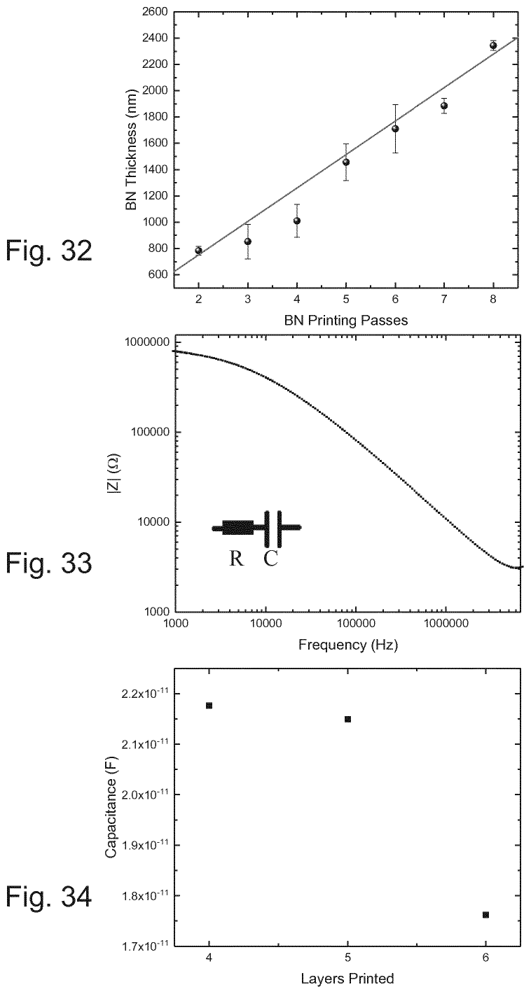

We investigate the dielectric properties of the h-BN ink in a Ag/h-BN/Ag parallel plate capacitor configuration. FIG. 28 shows a PET substrate 102 with a first layer 104 of silver, layer 106 of h-BN and a second layer 108 of silver. The capacitors are fabricated by inkjet-printing silver ink and h-BN ink layer-by-layer (FIGS. 29, 30, 31, showing the first, second and third steps of the device fabrication). A profilometer (DektakXT, Bruker) was used to determine the thickness (t) of each printed h-BN film as a function of the number of printing passes (FIG. 32), where a single printing pass is about 300 nm. To characterise the properties of the capacitors, impedance spectra (Agilent 4294A Precision Impedance Analyzer) were measured for each capacitor with varying h-BN film thickness (from about 1.2 μm to about 1.8 μm). A typical bode plot of the amplitude (|Z|) as a function of frequency are shown in FIG. 33 for a capacitor with h-BN film of thickness, t=1200 nm and area, A=500 μm² and presents a typical behaviour of a series R-C equivalent circuit [Kelly et al (2016)]. The capacitance is found to decrease with h-BN thickness (FIG. 34) as expected through the equation for a parallel plate capacitor C=εᵣε₀ A/t, where εᵣ is the relative permittivity and ε₀ is the vacuum permittivity. For an inkjet printed capacitor with an area of 500 μm² and thickness of 1.1 μm the capacitance is 8.7 nF/cm² which is consistent with the 0.24 to 1.1 nF/cm² range obtained by [Kelly et al (2016)] with a graphene/h-BN capacitor deposited by a inkjet printing (graphene) and spray coating (h-BN) techniques. Capacitors which were fabricated at t<1 μm were found to short circuit. Hence we select a thicknesses t of about 1.2 μm for our inkjet printed h-BN dielectric layer.

### Inkjet Printed Graphene/h-BN on PET:

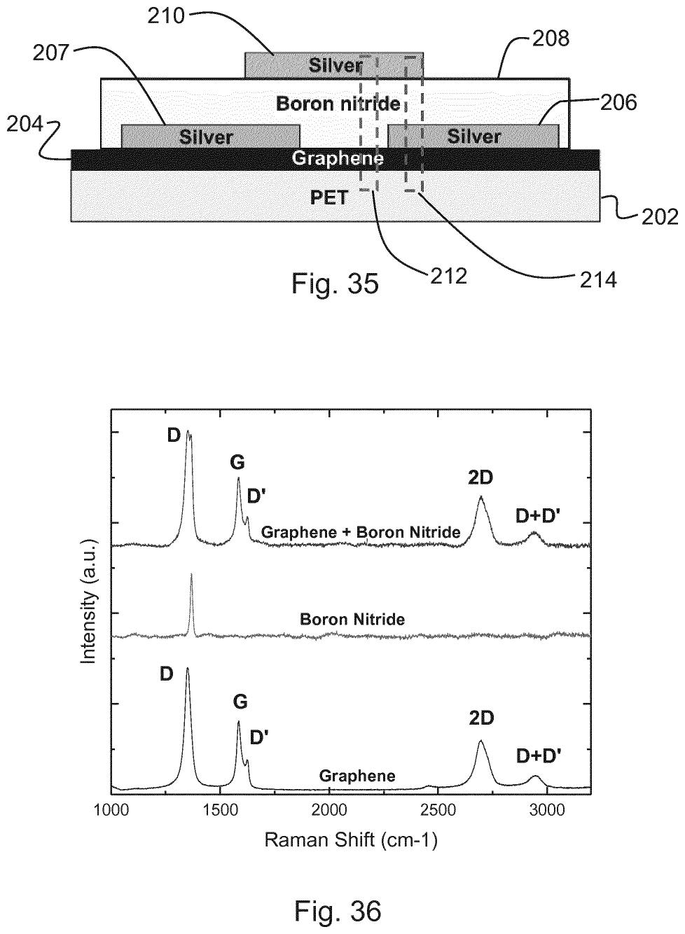

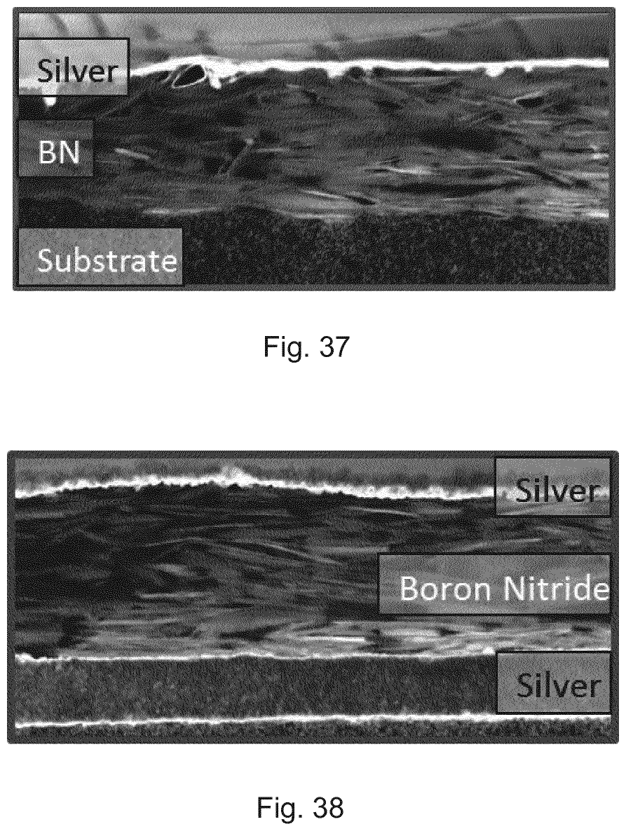

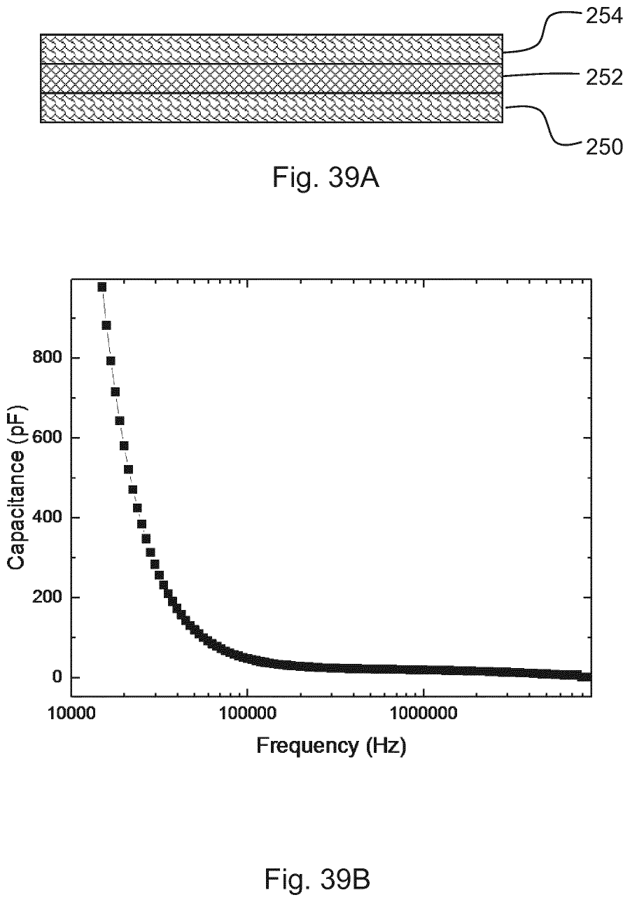

We first investigate bottom-gate top-contact (inverted staggered) and top-gate top-contact (coplanar) TFT structures and optimize the inkjet printed graphene/h-BN heterostructures on a PET substrate (Novele, Novacentrix) before moving to the technology onto polyester textile. The inverted staggered TFT structure is built up as shown through the schematic in FIG. 35, we first inkjet print the transistor channel 204 of t of about 100 nm (measured with AFM on Si/SiO₂) on a PET substrate 202 with the graphene ink, consistent with previously found percolation thresholds, followed by a inkjet printed source 206 and drain 207 (t of about 500 nm) (L of about 50 μm, W of about 580 μm) using a silver ink (Sigma Aldrich, 736465) (Z of about 3). The gate dielectric layer 208 is then inkjet printed with the h-BN ink forming a film of about 1.2 μm thickness and is placed under vacuum overnight at ambient temperature in order to remove any bubbles which may be trapped inside the dielectric. Finally a silver top gate 210 (t of about 200 nm) electrode is inkjet-printed on the structure and the sample is annealed on a hot plate at 100° C. for 1 hour to removed residual solvent. Using the same printing conditions the inverted staggered heterostructures are fabricated with L of about 65 μm, W of about 500 μm. High angle annular dark field scanning transmission electron microscopy (HAADF-STEM) cross sectional views (FIGS. 37, 38) of the coplanar graphene/h-BN TFT device are obtained from a focused ion beam (FIB) sectioned lamella (see methods, described below). FIG. 37 shows the channel region of the TFT (within region 212 indicated in FIG. 35) where the heterostructure of graphene and h-BN layers is sandwiched between the PET substrate and the silver electrode. FIG. 38 shows the top/bottom contact region of the TFT (within region 214 indicated in FIG. 35) where in this case the graphene/h-BN layers heterostructure is sandwiched between the gate (top) and drain (bottom) silver electrodes. In both cases, we identify a uniform and about 1.1 μm thick h-BN dielectric layer which matches the profilometry which was done in the previous section. The graphene and h-BN flakes are clearly visible and show a preferential alignment along the direction of the channel, with no visual evidence of pin-holes observed in the dielectric region due to the large (495 nm) lateral dimensions of the flakes. Multivariate analysis using non-negative matrix factorization (NMF) (FIG. 39) is used to confirm the chemical composition of the heterostructure. A comparison between the Carbon and Carbon and Oxygen NMF has been carried out, identifying the pristine graphene layer on the substrate. It seems likely that a Carbon and Oxygen signal from the h-BN layer comes from the CMC stabilization polymer, while the majority of the signal comes from boron and nitrogen as expected.

Raman spectroscopy (Reinshaw 1000 InVia micro-Raman) is used to monitor the quality of materials used in the heterostructure. FIG. 36 plots the spectra of inkjet printed films of graphene (black curve), h-BN (red curve), and graphene/h-BN heterostructure (blue curve), acquired at 514.5 nm on a Si/SiO₂ substrate. For the graphene the G peak located at 1580 cm⁻¹ corresponds to the high frequency E_{2g} phonon at the Brillouin zone centre Γ. The D peak located at about 1350 cm⁻¹ is due to the due to the breathing modes of sp² atoms and requires the existence of structural defects for its activation [Ferrari and Robertson (2000) and (2001); Tuinistra and Koenig (1970)]. The 2D peak located at 2695 cm⁻¹ is the D peak overtone and is usually composed of a single Lorentzian in single layer graphene, which splits into several components as the number of layer increases, reflecting the evolution of the electronic band structure [Ferrari et al (2006)]. The 2D peak is always seen, even when no D peak is present, since no defects are required for the activation of two phonons with the same momentum, one backscattering from the other. In pristine graphene inks the D and D′ peaks correspond to the edges of the submicrometer flakes, rather than to the presence of a large amount of disorder within the flakes [Torrisi et al (2012); Casiraghi et al (2009)]. This is supported by our graphene film showing a low Disp(G) of about 0.01 cm⁻¹/nm, which is lower than what expected for disordered carbon [Ferrari and Robertson (2000)]. In disordered carbons, the G peak position, Pos(G), increases as the excitation wavelength λ_{L} decreases from the IR to UV [Ferrari and Robertson (2001)]. Therefore, the dispersion of the G peak, Disp(G)=ΔPos(G)/Δλ_{L} increases with disorder and allows one to discriminate between disorder localized at the edges or in the bulk of the samples [Ferrari and Robertson (2001); Casiraghi et al (2009)]. Moreover, a single Lorentzian fit of the 2D peak indicates that the graphene film is comprised of electronically decoupled graphene layers. In the case of the h-BN film (red curve) we observe a single peak at 1368 cm⁻¹ corresponding to the E_{2g} phonon vibration mode [Reich et al (2005); Gorbachev at al (2011)]. Typically for bulk h-BN this peak is found at 1366 cm⁻¹ while the upshifting of the peak indicates the successful exfoliation from the bulk material to few layer h-BN [Gorbachev at al (2011)]. The Raman spectrum of the graphene/h-BN heterostructure (blue curve) shows the fingerprints of graphene flakes and h-BN flakes. The spectrum is in fact the superimposition of that of the graphene film and the h-BN film, indicating that the materials are not interacting with each other.

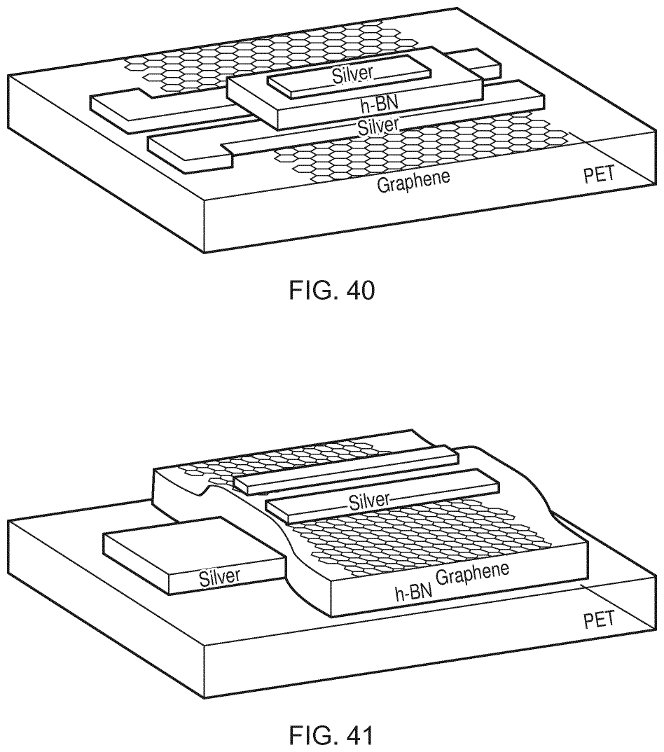

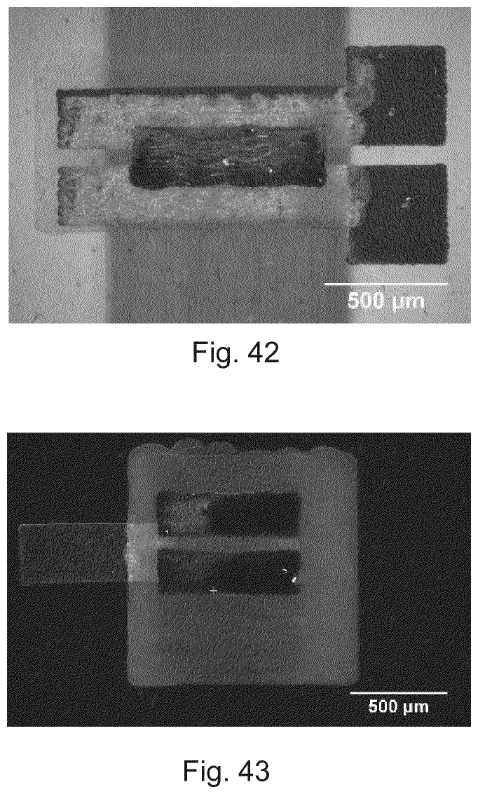

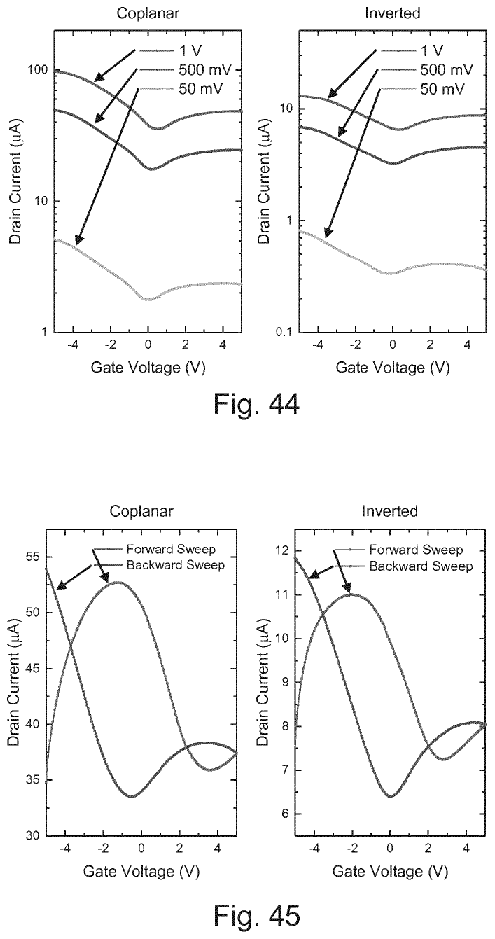

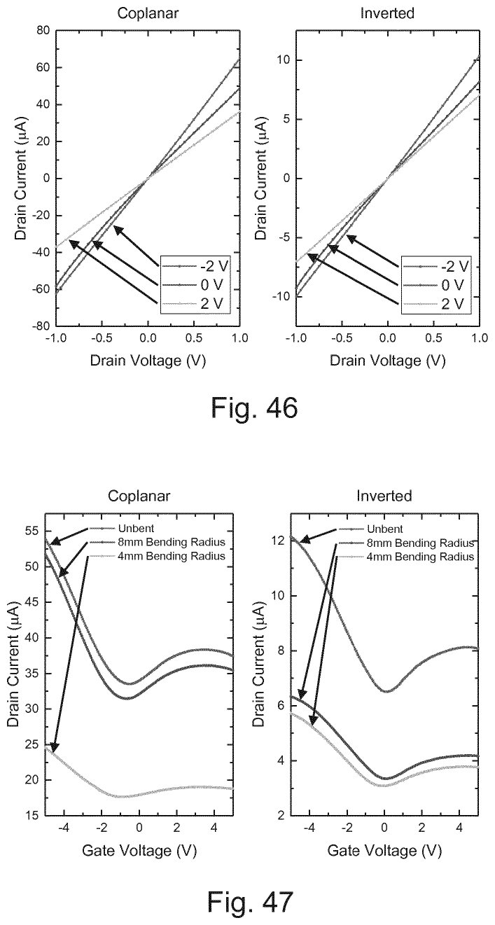

We then characterise the output and transfer electrical characteristics of both coplanar (FIG. 40) and inverted staggered (FIG. 41) graphene/h-BN TFTs on PET. For both structures, the transfer characteristics (shown in FIG. 44) are measured (at room conditions) applying drain-source voltage Vds=1V, 500 mV, 50 mV, and the output characteristics (FIG. 46) measured at Vgs=−2, 0, and 2 V indicate that drain current (Id) increases linearly with Vds which is typical of zero-bandgap semiconductors and consistent with the behaviour of graphene TFTs [Schwierz (2010)]. From FIG. 45 we observed ambipolar behaviour for both device structures [Schwierz (2010)] (V_{ds}=1V) on all the coplanar and staggered graphene/h-BN printed devices as is expected for graphene-based TFTs [Schwierz (2010); Lemme et al (2008)]. The gate leakage in the devices is a magnitude lower (about 100 nA) than the drain current indicating that the device is modulating current in the graphene channel. When a forward Vgs sweep (from negative to positive Vgs) is applied (black curve) in top-gated devices (FIG. 43) the minimum drain current (I_{d}), corresponding to the charge neutrality point (i.e. Dirac point in graphene), occurs at positive voltage, which means graphene channel was lightly p-doped. However, we notice a hysteretic behaviour when a forward gate-source voltage Vgs sweep (from more negative to more positive Vgs) is applied, which causes a shift of the Dirac point of ΔV of about 3V between forward Vgs sweep and backwards Vgs sweep. This is consistent with ΔV already observed in TFTs fabricated by CVD-grown graphene and mechanical cleavage graphene [Wang et al (2010)]. In our devices we attribute this effect to likely arise from capacitive gating created by the oppositely charged ions of residual water in the device which can enhance the local electrical field at the graphene/h-BN interface and help attract more majority carriers through the metallic contact [Wang et al (2010)]. Furthermore we observed an artefact at the start of each sweep which is seen as a sharp increase in Id with more positive gate voltages Vg which we attribute to charge transfer to the dielectric [Wang et al (2010)].

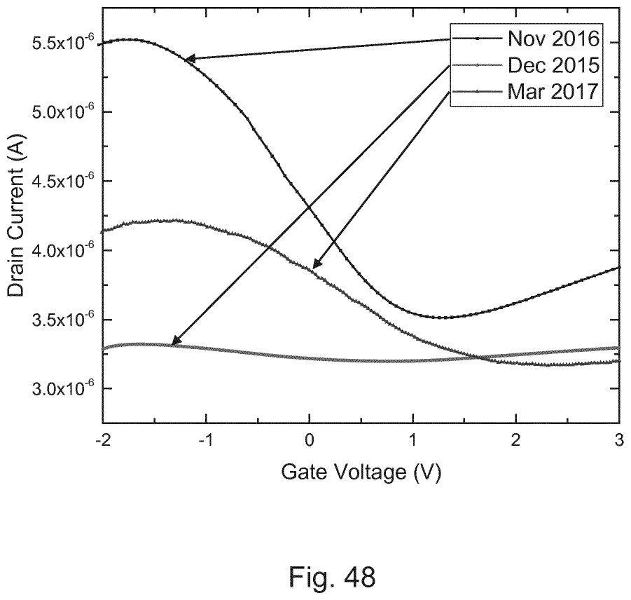

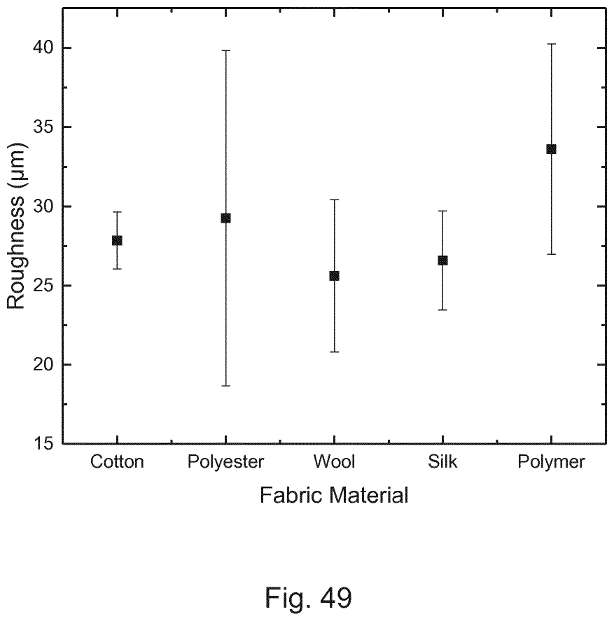

The field effect mobility (μ) of the coplanar and inverted staggered devices are derived from the slope of the transfer characteristic according to p=(L/W*C*V_{ds})/(dl_{d}/dV_{gs}), where L [μm] and W [μm] are the channel length and width, respectively, and C dielectric capacitance [Schwierz (2010)]. We use the previously calculated dielectric capacitance of 8.7 nF/cm² at a drain voltages of 1 V_{ds}. The hole mobility (μₕ) and electron mobility (μₑ) of the coplanar devices are calculated to be 150±18 cm² V⁻¹ s⁻¹ and 78±10 cm² V⁻¹ s⁻¹ respectively while having an on/off current ratio (defined as the maximum I_{d} divided by the minimum I_{d}) of about 2.5±0.1. For the inverted staggered devices we find an ON/OFF ratio of about 1.5±0.2, μₕ=32±5 cm² V⁻¹ s⁻¹ and μₑ=10±4 cm² V⁻¹ s⁻¹ which is one magnitude lower than the non-inverted structure field effect mobility on PET, we attribute this decrease in mobility to the rougher surface of the h-BN layer (Rq=68 nm, determined by AFM) in contrast to the PET film (Rq=15.2 nm) which could affect the stacking quality of the graphene flakes. Such difference between hole and electron mobility corresponds to a preferential hole conduction over electron conduction, which may be due in part to the unintentional extrinsic doping [Lemme at al (2008); Liang et al (2010)]. Such preferential hole conduction has been reported for various sources of graphene, including graphene synthesized by CVD[Suk et al (2013)] and mechanical exfoliation [Lemme at al (2008)]. The field effect mobility is higher than printed carbon nanotube TFT's (p of about 20 cm² V⁻¹ s⁻¹, on/off of about 10⁴) [Ha et al (2010)] and is about 15 times higher than the best organic (p of about 10.5 cm² V⁻¹ s⁻¹, on/off of about 10⁶) [Li et al (20120)] and oxide transistors (μₑ of about 9 cm² V⁻¹ s⁻¹, on/off of about 10⁷) [Huang at al (2016)] while comparable to inkjet printed graphene TFT's (p=95 cm² V⁻¹ s⁻¹, on/off of about 10) [Torrisi et al (2012)] and reduced graphene oxide (rGO) transistors (p of about 210 cm² V⁻¹ s⁻¹, on/off of about 3) [Su et al (2010)]. However the on/off ratio is lower than that of organic, oxide and CNT transistors [Ha et al (2010); Li et al (20120); Huang at al (2016)], this is however consistent with the on/off measured on previously reported TFTs from graphene [Torrisi (2012); Su et al (2010)]. The flexibility of the coplanar device was tested as a function of bending radius using metal rods (FIG. 47), we observe no change in the device mobility at a bending radius of 8 mm, while when a smaller bending radius was used (4 mm) the hole mobility drops to about 19 cm² V⁻¹ s⁻¹. The coplanar device stability of a printed graphene FETs was also examined over a 2 year period and we observe that that device is still operational (FIG. 48). We attribute this behaviour to the environmental stability of graphene [Bonaccorso et al (2010)] and the longevity of the h-BN encapsulated properties [Wang et al (2013)]. However while the device characteristics were relatively unchanged we notice that the Dirac point slowly shifts over time. It is likely oxygen is slowly diffusing though the BN layer and doping of the channel over time [Lee et al (2010)]. Moreover we notice that the ON/OFF ratio increases slightly from 1.03 to 1.57, possibly due to an improvement in the graphene-metal contact resistance as a result of residual high boiling point solvents slowly evaporating from the silver contact [Xia et al (2010)]. In FIG. 47 (right hand side) we demonstrate the flexibility of the inverted staggered device and find that device mobility decreases to μₚ of about 6 cm² V⁻¹ s⁻¹ once bent by a bending radius of 8 mm.

### All Inkjet Printed Graphene Transistor on Textile:

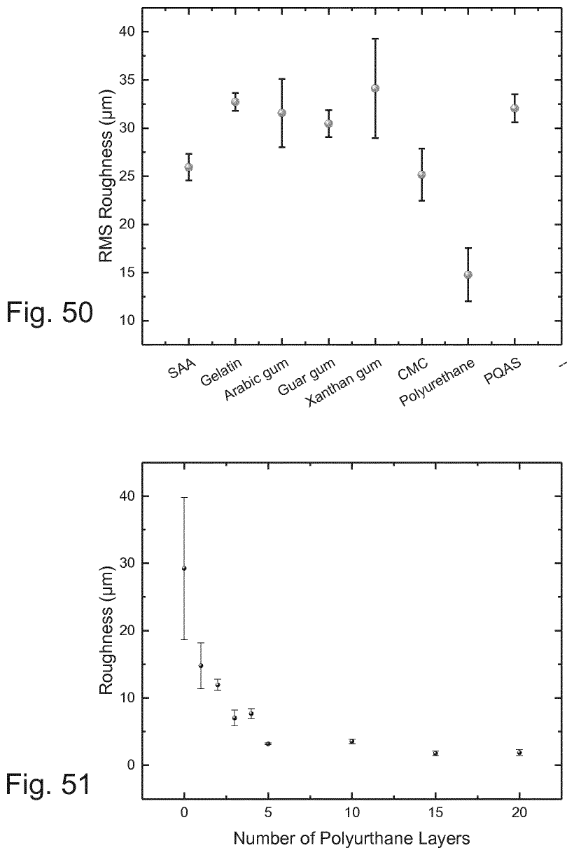

The decrease in field effect mobility resulting from the small (about 50 nm) increase in surface roughness between the coplanar and inverted staggered heterostructure on PET emphasizes the importance of roughness minimisation for the implementation of high performance devices on textile where Rq is typically in the range of about 30 μm. Therefore before transferring the inverted staggered heterostructure to textile, we adopt an additional solution to improve performance in our textile devices through the use of a planarization layer. Typically building components on the weave of the textile requires the use of a planarization layer such as Polydimethylsiloxane (PDMS) [Khan et al (2012)], polyimide [Sekitani et al (2010)], polyurethane [Kim et al (2013)] or poly(vinyl alcohol) (PVA) [Kim et al (2015)] to decrease the rms roughness and thus improve performance of devices [Peng and Change (2014)]. For example, Kim et al (2013) used laminated polyurethane (t of about 20-50 μm) on polyester reducing the rms roughness from 10 μm to <5 μm, while Sekitani et al (2010) used spin coated polyimide (t of about 500 nm) on polyimide, reducing the rms roughness from 2.5 nm to 0.3 nm. Here, we choose to use polyester satin fabric as a substrate for our wearable graphene-h-BN TFTs because it is very durable and represents about about 80% of the 2016 synthetic fibre market [Krifa and Stewart-Stevens (2016)]. To determine a suitable planarization layer we rod coat (K202 RK coating machine) the polyester with eight different materials; sodium alga acid (SAA), gelatin, arabic gum, guar gum, xanthan gum, sodium carboxymethylcellulose (CMC), polyurethane, polymerizable quaternary ammonium salt (PQAS) and measured their rms roughness using a profilometer (DektakXT, Bruker) (FIG. 50). After coating, the fabric is annealed at 60° C. in oven (Genlab) for 20 min. FIG. 50 shows the profilometry measurement for all the planarization layers. Polyurethane-coated fabric is identified as having the lowest rms roughness of 14.8 μm after one coating layer (about 600 nm), as compared to the other coating layers where an rms roughness between 25-34 μm was measured. We also investigated the effect of multi-stacked planarization layers by applying several coatings of polyurethane on polyester from 1 to 20 layers (FIG. 51). We notice a decrease of the rms roughness as a function of the number of coating passes and after 20 layers we achieve an rms roughness decrease from 29±10 μm to 1.9±0.5 μm. Therefore we adopt this about 12 μm coating layer when fabricating our textile devices. Despite the low roughness (1.9 μm) we attempted to print thin graphene lines between 100-200 nm consistent with the thickness previously used in the PET TFTs. However, the graphene lines was unconductive (due to the roughness of the substrate) which hinders the development of a coplanar structure on our polyurethane coated textile, moreover increasing the thickness of the graphene layer further will inevitably decrease the transistor mobility [Torrisi et al (2012)]. Despite the poorer performance of the inverted staggered heterostructure on PET we adopt this final layout for our wearable graphene/h-BN TFT as it offers higher resilience to roughness variation of the substrate than the coplanar structure, given that the channel sits on the top of a h-BN interface.

In addition, wearable electronic devices require not only flexibility, but to preserve the same stretchability of the fabric with little or no effect on the electrical and optical performances. Hence, we replace the printed silver electrodes with a stretchable polymer such as poly(3,4-ethylenedioxythiophene) polystyrene sulfonate (PEDOT:PSS) (Sigma-Aldrich, 739316, 0.8 w/v in H₂O) (Z of about 30) [Vosgueritchian et al (2012)].

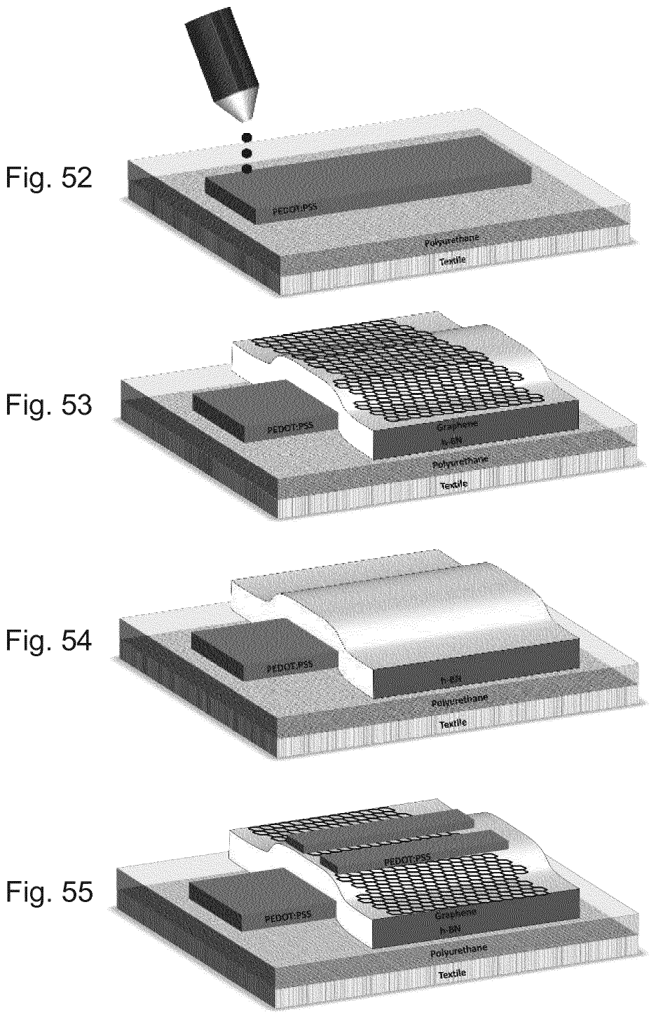

FIGS. 52-55 show the sequence of steps of the inkjet printing for fabrication of the textile TFT heterostructure. The all-inkjet printed textile TFT is fabricated as follows. First we deposit a 6.5 μm thick electrode (determined by profilometry) of PEDOT:PSS as the gate, then print a h-BN layer of thickness about 1.1 μm followed by a 100 nm thick graphene channel and finally deposition of PEDOT:PSS about 800 nm thick source and drain contacts. We find that with the additional PEDOT:PSS/h-BN component of the hetrostructure decreased the rms further from 1.9 μm to 588 nm (determined by AFM). Similarly to the PET devices the samples were annealed at 100° C. for 1 hour to remove residual solvent in the device.

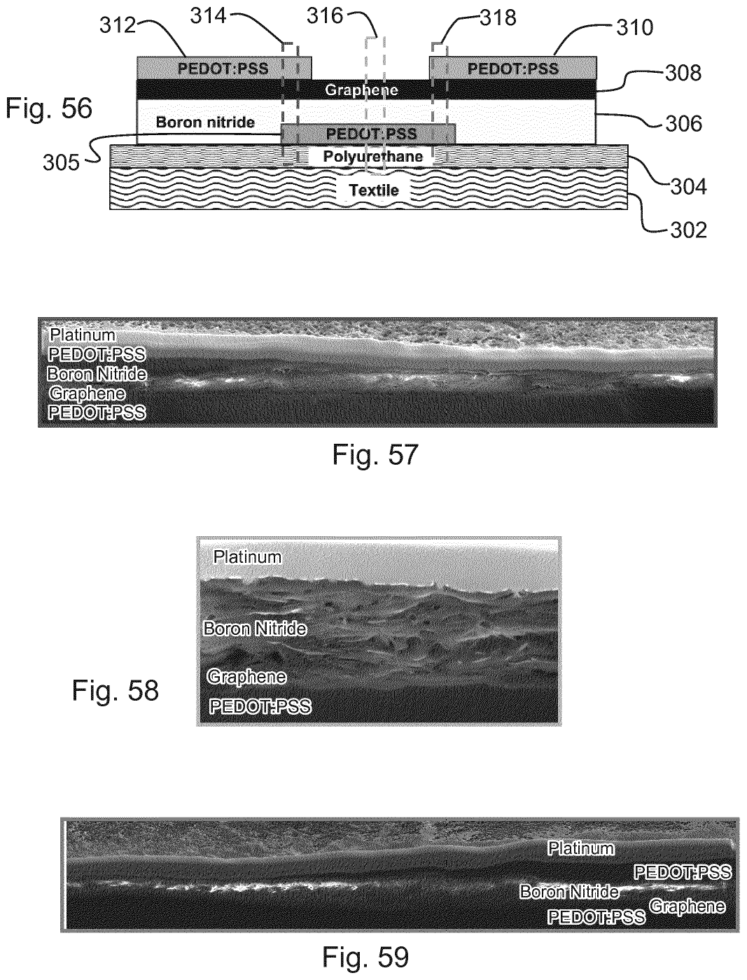

FIG. 56 shows a schematic cross sectional view of the textile TFT device. Textile substrate 302 is coated with a smoothing layer 304. Gate electrode 305 is formed from PEDOT-PSS. H-BN dielectric layer 306 is then formed over the gate electrode. Channel layer 308 is formed from graphene, followed by source and drain contacts 310, 312, both formed from PEDOT-PSS. FIGS. 57, 58 and 59 show FIB-SEM cross section views of the textile TFT device though the left contact 312 (region 314), middle channel (region 316) and right contact 310 (region 318) indicated on FIG. 56. The geometry of all the graphene/h-BN textile TFTs is L of about 80 μm, W of about 500 μm, and t of about 100 nm as shown in the images of the wearable graphene/h-BN TFT.

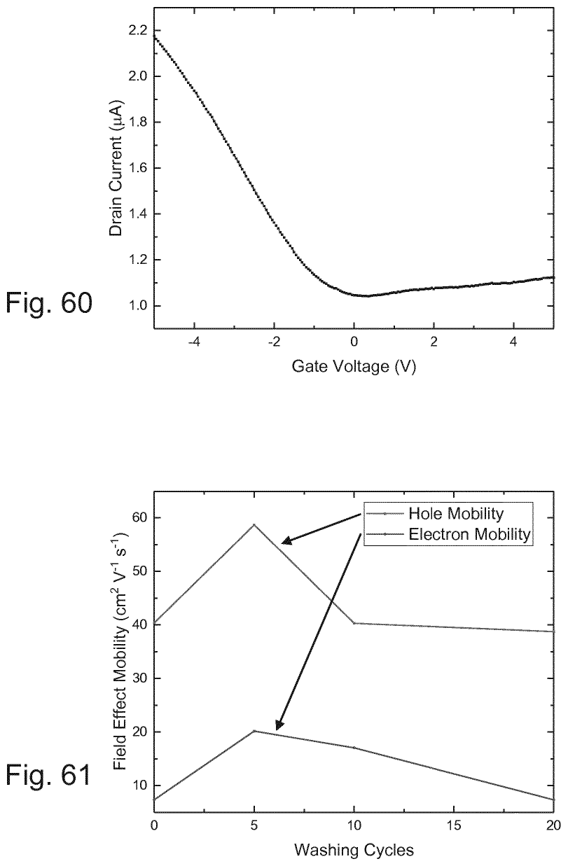

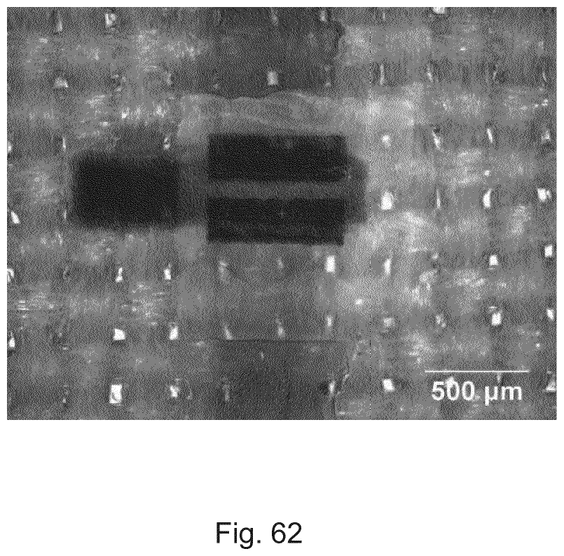

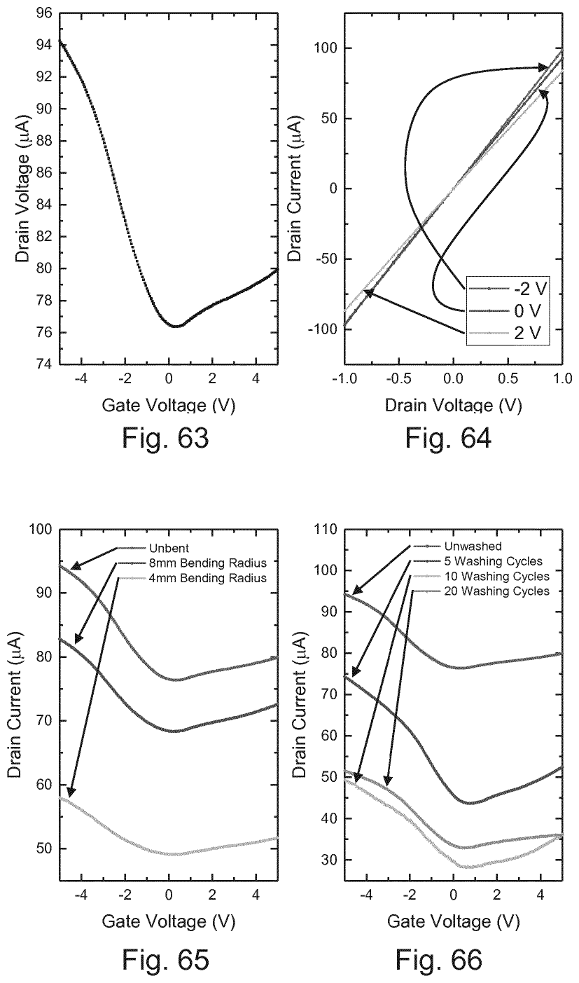

FIG. 60 plots the transfer characteristic at Vds=1V, similarly to the graphene/h-BN TFT on PET we observe ambipolar behaviour and obtain an average mobility μₕ=6±2 cm² V⁻¹ s⁻¹, μₑ=2±1 cm² V⁻¹ s⁻¹ respectively, and ON/OFF ratio of about 2.0±0.1. These mobilities are one magnitude lower than values obtained on for the inverted staggered graphene/h-BN TFT on PET likely due to the increase of the roughness of the h-BN layer from Rq=68 nm to Rq=588 nm. However by increasing the graphene thickness to about 200 nm, we decrease the channel resistance from 500 kΩ to 10 kΩ and help to percolate the graphene flakes. FIG. 63 plots the transfer characteristic at Vds=1V and FIG. 64 plots the output characteristic for different gate voltages Vgs=−2, 0 and 2V. The field effect mobility of the devices improves by one magnitude μₕ=73±23 cm² V⁻¹ s⁻¹ and μₑ=18±8 cm² V⁻¹ s⁻¹ respectively, while the ON/OFF ratio stays consistent (about 2.1±0.3). This behaviour is expected, since it has previously been shown that field effect mobility increases with thickness until percolation is reached [Torrisi et al (2012)]. The field effect mobility is two to three magnitudes larger than what has currently been achieved for organic FETs for e-textile fibers (ρ of about 0.01-0.3 cm² V⁻¹ s⁻¹, on/off of about 10³) [Maccione et al (2006); Mattana et al (2011); Nam et al (2012)] while reaching one magnitude greater mobility than inverted staggered TFTs fabricated on polyester textile with a ion gel dielectric/P3HT smoothing layer (p of about 7 cm² V⁻¹ s⁻¹, on/off of about 10⁵) [Kim et al (2016)]. It is worth also mentioning that our device operates at low voltage (<5 V) which is important for wearable electronics as devices on the users clothes require low power consumption so that they can operate from energy harvesting systems (such as piezoelectric systems) embedded within the textile [Qi et al (2010)].

Wearable textile devices will normally undergo naturally occurring tensile strain as well as washing steps [Ren et al (2017)]. We then investigate the effect of bending (FIG. 65) on the mobility of the graphene/h-BN TFT. We find that μₕ decreases to 33 cm² V⁻¹ s⁻¹ at 8 mm bending radius which drops again to 21 cm² V⁻¹ s⁻¹ at 4 mm bending radius and indicating that the devices still function well when bent which is exceptionally important in textiles so that the user can move around without damaging the wearable components [Matsuhisa (2015)].

In FIG. 66, the washability of the textile TFTs was tested to determine the expected lifetime of devices which might incorporate the FET for wearable electronics. To protect the devices a waterproof polyurethane protective layer (WBM Seam Tapes) was hot pressed (PixMax Swing heat press) around the top and bottom of the devices at 120° C. for 5 seconds. For each washing test, the sample was washed with 100 mL deionized water containing 2 mg/ml sodium carbonate and 5 mg/ml soap at 40° C. for 30 min according to industry standards [Ren et al (2017)]. The devices were functional up to 20 washing cycles without any significant change to the performance of the devices (FIG. 61).

Additional work is now reported on Graphene/h-BN/Graphene fabric capacitors. A cotton or polyester fabric (but not limited to) in size of 1 cm×2 cm is cleaned by deionized water and then are dried in oven at 60° C. The fabric can optionally be treated with a cationic or anionic modification agent to improve adhesion of the 2d material. The cleaned polyester fabrics are immersed into a graphene dispersion for 3 min with continuous stirring. Then the soaked fabric is stuck on glass slide and dried at 60° C. for 5 min. This ‘dip and dry’ procedure can be marked as one cycle and repeated for several cycles to put more graphene into the fabric. Then the graphene fabrics are processed by hot pressing at 200° C. for several minutes. This can be repeated for a h-BN dispersion to create h-BN fabrics. The graphene/h-BN/graphene structure can then be assembled together by using PVA glue at the edges of the fabrics. The structure is then hot pressed again to improve adherence between the layers. FIG. 39A shows a schematic view of such a structure, in which h-BN textile layer 252 is sandwiched between graphene textile layers 250, 254. FIG. 39B shows the typical impedance spectra of the capacitive structure of FIG. 39A, obtained with an impedance analyser. The response follows a R-C equivalent circuit model.

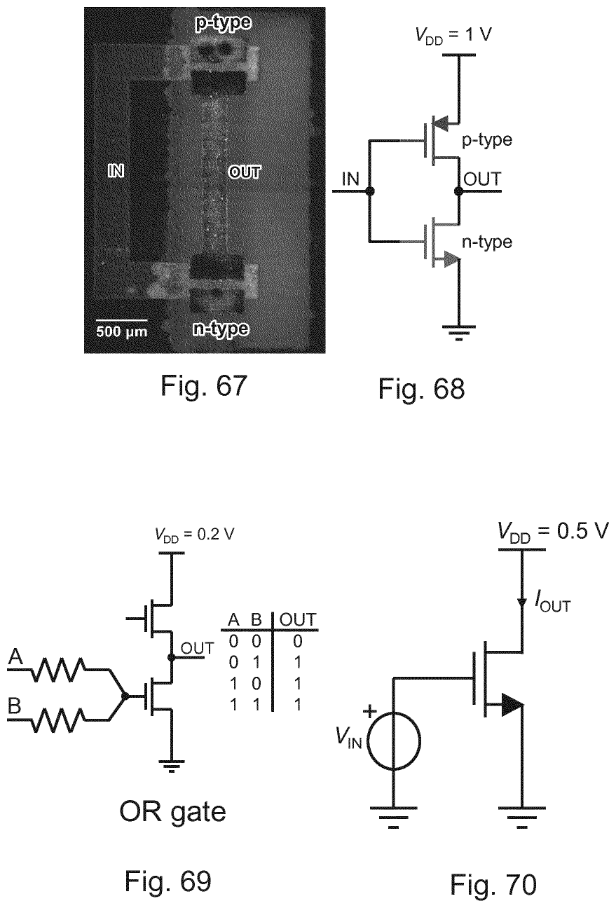

As indicated above, it is also possible to fully inkjet print flexible electronic components, including complete circuits, according to embodiments of the invention. FIG. 67 shows an image obtained using optical microscopy (dark field) of an integrated circuit demonstrating an all inkjet-printed complementary graphene inverter. The inverter is shown in schematic of FIG. 68. FIG. 69 shows a circuit diagram of a multifunctional printed logic gate with two inputs (A and B) and one output (OUT) with truth table of an OR logic gate. FIG. 70 shows a schematic of a memory cell capable of being fully inkjet printed.

### Conclusions:

We have demonstrated fully inkjet printed graphene FETs on PET and polyester fabric, and more complex electronic components. Both LPE and microfluidization inks are ideal low-cost production techniques to engineering printable inks for heterostructure devices. These inks can be easily deposited by inkjet creating FET heterostructures on demand. We show that the mobility of these devices decreases significantly as the channel roughness increases. The devices are flexible and maintain their functionality over time even over periods of 2 years. Moreover the FETs on textile are demonstrated to be washable for up to 20 cycles, enhancing their lifetime which can cut replacement costs and improve compatibly with current textile industry technologies. These transistors present a new application for 2D inks in active devices with the competitive advantage over conventional silicon based electronics as they are fully printed at room temperature minimising the number of processing steps and the overall cost involved.

### Methods

We refer to the experimental methods set out earlier. Here, certain additional methods, applicable to the reported work on inkjet printed electronic devices, are set out.

### Solvent Exchange:

First (˜20 ml) of graphene/NMP ink is passed through a PTFE membrane (Merck Millipore, 0.1 μm). The process is hastened with the use of Büchner flask which is attached to a vacuum pump. The membrane is then placed into 5 ml of ethanol and bath sonicated (Fisherbrand FB15069, Max power 800 W) for 10 min to redisperse the flakes into the ethanol.

### Raman Spectroscopy:

Films of each ink and a Gr/h-BN heterostructure are inkjet printed on Si/SiO2 substrate and the Raman spectra are acquired with a Reinshaw 1000 InVia micro-Raman spectrometer at 457, 514.5, and 633 nm and a ×20 objective, with an incident power of below ˜1 mW to avoid possible thermal damage. The G peak dispersion is defined as Disp(G)=ΔPos(G)/ΔλL, where λL is the laser excitation wavelength.

### Scanning Electron Microscopy:

Scanning electron microscopy images were taken with a high resolution Magellan 400 L scanning electron microscope (SEM). The field emission gun was operated at an accelerating voltage of 5 KeV and gun current of 6.3 pA. Images were obtained in secondary electron detection mode using an immersion lens and TLD detector.

### Atomic Force Microscopy:

A Bruker Dimension Icon working in peakforce mode was used. From the centrifuged graphene and BN dispersions samples were collected and after 10 times dilution they were drop casted onto pre-cleaned (with acetone and isopropanol) Si/SiO2 substrates wafer substrates. For the graphene and BN inks, 150 flakes were counted to determine the statistics for the lateral size and thickness. For the rms roughness measurements areas of 50 μm² were scanned.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

All references referred to above are hereby incorporated by reference.

### NON-PATENT DOCUMENT REFERENCES

Akinwande, D., Petrone, N. & Hone, J. Two-dimensional flexible nanoelectronics. Nat. Commun. 5, 5678 (2014).
Babu K F, Dhandapani P, Maruthamuthu S, et al. One pot synthesis of polypyrrole silver nanocomposite on cotton fabrics for multifunctional property[J]. Carbohydrate polymers, 2012, 90(4): 1557-1563.
Baeg, K. J., Caironi, M. & Noh, Y. Y. Toward printed integrated circuits based on unipolar or ambipolar polymer semiconductors. Adv. Mater. 25, 4210-4244 (2013).
Bonaccorso, F., Sun, Z., Hasan, T. & Ferrari, A. C. Graphene Photonics and Optoelectronics. Nat. Photonics 4, 611-622 (2010).
Casiraghi et al. Raman Spectroscopy of Graphene Edges, Nano Lett., 2009, 9 (4), pp 1433-1441.
Chang, C. K. et al. Band gap engineering of chemical vapor deposited graphene by in situ BN doping. ACS Nano 7, 1333-1341 (2013).
Charles M. Hansen. Hansen Solubility Parameters: A User's Handbook. (CRC Press Inc., 2007).
Chauraya, A. et al. Inkjet printed dipole antennas on textiles for wearable communications. IET Microwaves, Antennas Propag. 7, 760-767 (2013).
Chen, P., Chen, H., Qiu, J. & Zhou, C. Inkjet printing of single-walled carbon nanotube/RuO2 nanowire supercapacitors on cloth fabrics and flexible substrates. Nano Res. 3, 594-603 (2010).
Cheng Y, Wang R, Sun J, et al. Highly Conductive and Ultrastretchable Electric Circuits from Covered Yarns and Silver Nanowires[J]. ACS nano, 2015, 9(4): 3887-3895.;
Cherenack K, Zysset C, Kinkeldei T, et al. Woven electronic fibers with sensing and display functions for smart textiles[J]. Advanced materials, 2010, 22(45): 5178-5182;
De, S. & Coleman, J. N. The effects of percolation in nanostructured transparent conductors. MRS Bull. 36, 774-781 (2011).
DeGans, B. J.; Duineveld, P.; Schubert, U. Inkjet Printing of Polymers: State of the Art and Future Developments. Adv. Mater. 2004, 16, 203-213.
Derby, B. & Reis, N. Inkjet Printing of Highly Loaded Particulate Suspensions. MRS Bull. 28, 815-818 (2003).
Dong, H., Carr, W. W. & Morris, J. F. An experimental study of drop-on-demand drop formation. Phys. Fluids 18, (2006).
Ferrari, A. C. & Robertson, J. Interpretation of Raman spectra of disordered and amorphous carbon. Phys. Rev. B 61, 14095-14107 (2000).
Ferrari, A. C. & Robertson, J. Resonant Raman spectroscopy of disordered, amorphous, and diamondlike carbon. Phys. Rev. B 64, 75414 (2001).
Ferrari, A. C. et al. Raman spectrum of graphene and graphene layers. Phys. Rev. Lett. 97, (2006).
Ferrari, A. C. et al. Science and technology roadmap for graphene, related two-dimensional crystals, and hybrid systems. Nanoscale 7, 4598-4810 (2014).
Fromm, J. E. Numerical Calculation of the Fluid Dynamics of Drop-on-Demand Jets. IBM J. Res. Dev. 28, 322-333 (1984).
Gao, G. et al. Artificially stacked atomic layers: Toward new van der waals solids. Nano Lett. 12, 3518-3525 (2012).
Geim, A. K. & Grigorieva, I. V. Van der Waals heterostructures. Nature 499, 419-425 (2013).
Gomez De Arco, L. et al. Continuous, highly flexible, and transparent graphene films by chemical vapor deposition for organic photovoltaics. ACS Nano 4, 2865-2873 (2010).
Gorbachev, R. V. et al. Hunting for monolayer boron nitride: Optical and raman signatures. Small 7, 465-468 (2011).
Gualandi, I. et al. Textile Organic Electrochemical Transistors as a Platform for Wearable Biosensors. Sci. Rep. 6, 33637 (2016).
Ha, M. et al. Printed, sub-3V digital circuits on plastic from aqueous carbon nanotube inks. ACS Nano 4, 4388-4395 (2010).
Hasan T, Torrisi F, Sun Z, et al. Solution-phase exfoliation of graphite for ultrafast photonics. Phys Status Solidi Basic Res. 2010; 247(11-12):2953-2957.
Heeger, A. J. Semiconducting and metallic polymers: The fourth generation of polymeric materials. Curr. Appl. Phys. 1, 247-267 (2001).
Hernandez, Y. et al. High yield production of graphene by liquid phase exfoliation of graphite. Nat. Nanotechnol. 3, 563-8 (2008).
Hideki, S., Louis, E. J., MacDiarmid, A. G., Chiang, C. K. & Heeger, A. J. Synthesis of Electrically-Conducting organic Polymers: Halogen Derivatives of Polyacatylene, (CH)x. J.C.S., Chem. Commun. 1-5 (1977).
Huang, W. et al. Metal Oxide Transistors via Polyethylenimine Doping of the Channel Layer: Interplay of Doping, Microstructure, and Charge Transport. Adv. Funct. Mater. 26, 6179-6187 (2016).
Jang Y, Park Y D, Lim J A, et al. Patterning the organic electrodes of all-organic thin film transistors with a simple spray printing technique[J]. Applied physics letters, 2006, 89(18): 183501.
Jang, D., Kim, D. & Moon, J. Influence of fluid physical properties on ink-jet printability. Langmuir 25, 2629-2635 (2009).
Jost K, Perez C R, McDonough J K et al., “Carbon coated textiles for flexible energy storage,” Energy and Environmental Science 4 (12), 5060-5067.Lee X, Yang T, Li X, et al. Flexible graphene woven fabrics for touch sensing[J]. Applied Physics Letters, 2013, 102(16): 163117;
Karagiannidis, P. G. et al. Microfluidization of Graphite and Formulation of Graphene-Based Conductive Inks. ACS Nano (2017).
Kelly, A. G., Finn, D., Harvey, A., Hallam, T. & Coleman, J. N. All-printed capacitors from graphene-BN-graphene nanosheet heterostructures. Appl. Phys. Lett. 109, (2016).
Khan, M. A., Bhansali, U. S. & Alshareef, H. N. High-performance non-volatile organic ferroelectric memory on banknotes. Adv. Mater. 24, 2165-2170 (2012).
Kim, H., Kwon, S., Choi, S. & Choi, K. C. Solution-processed bottom-emitting polymer light-emitting diodes on a textile substrate towards a wearable display. J. Inf. Disp. 16, 179-184(2015).
Kim, S. J., We, J. H. & Cho, B. J. A wearable thermoelectric generator fabricated on a glass fabric. Energy Environ. Sci. 7, 1959 (2014).
Kim, W. et al. Soft fabric-based flexible organic light-emitting diodes. Organic Electronics 14, (2013).
Kim, Y. et al. Flexible Textile-Based Organic Transistors Using Graphene/Ag Nanoparticle Electrode. Nanomaterials 6, 147 (2016).
Kopola, P., Tuomikoski, M., Suhonen, R. & Maaninen, A. Gravure printed organic light emitting diodes for lighting applications. Thin Solid Films 517, 5757-5762 (2009).
Kouroupis-Agalou, K. et al. Fragmentation and exfoliation of 2-dimensional materials: a statistical approach. Nanoscale 6, 5926-5933 (2014).
Kravets V G, Grigorenko A N, Nair R R, et al. Spectroscopic ellipsometry of graphene and an exciton-shifted van Hove peak in absorption. Phys Rev B—Condens Matter Mater Phys. 2010; 81(15).
Krebs, F. C. Fabrication and processing of polymer solar cells: A review of printing and coating techniques. Solar Energy Materials and Solar Cells 93, 394-412 (2009).
Krebs, F. C. Polymer solar cell modules prepared using roll-to-roll methods: Knife-over-edge coating, slot-die coating and screen printing. Sol. Energy Mater. Sol. Cells 93, 465-475 (2009).
Krifa, M. & Stewart Stevens, S. Cotton Utilization in Conventional and Non-Conventional Textiles-A Statistical Review. Agric. Sci. 7, 747-758 (2016).
Lakafosis, V. et al. Progress towards the first wireless sensor networks consisting of inkjet-printed, paper-based RFID-enabled sensor tags. Proc. IEEE 98, 1601-1609 (2010).
Lau, P. H. et al. Fully printed, high performance carbon nanotube thin-film transistors on flexible substrates. Nano Lett. 13, 3864-3869 (2013).
Lee, B. et al. Modification of electronic properties of graphene with self-assembled monolayers. Nano Lett. 10, 2427-2432 (2010).
Lee, C., Wei, X., Kysar, J. W., Hone, J. &=. Measurement of the Elastic Properties and Intrinsic Strength of Monolayer Graphene. Science (80-.). 321, 385-388 (2008).
Lemme, M. C. et al. Mobility in graphene double gate field effect transistors. Solid. State. Electron. 52, 514-518 (2008).
Li Y, Torah R, Beeby S P, et al. Inkjet printed flexible antenna on textile for wearable applications[J]. 2012.
Li, J. et al. A stable solution-processed polymer semiconductor with record high-mobility for printed transistors. Sci. Rep. 2, 754 (2012).
Liang, X. et al. Formation of bandgap and subbands in graphene nanomeshes with sub-10 nm ribbon width fabricated via nanoimprint lithography. Nano Lett. 10, 2454-2460 (2010).
Lin, R., Li, A., Lu, L. & Cao, Y. Preparation of bulk sodium carboxymethyl cellulose aerogels with tunable morphology. Carbohydr. Polym. 118, 126-132 (2015).
Liu B T, Kuo H L. Graphene/silver nanowire sandwich structures for transparent conductive films[J]. Carbon, 2013, 63: 390-396;
Liu X, Chang H, Li Y, et al. Polyelectrolyte-bridged metal/cotton hierarchical structures for highly durable conductive yarns[J]. ACS applied materials & interfaces, 2010, 2(2): 529-535.
Liu, Z. et al. Transparent conductive electrodes from graphene/PEDOT:PSS hybrid inks for ultrathin organic photodetectors. Adv. Mater. 27, 669-675 (2015).
Loh K P, Bao Q, Ang P K, et al. The chemistry of graphene[J]. Journal of Materials Chemistry, 2010, 20(12): 2277-2289.
Lotya, M. et al. Liquid phase production of graphene by exfoliation of graphite in surfactant/water solutions. J. Am. Chem. Soc. 131, 3611-3620 (2009).
Maccioni, M., Orgiu, E., Cosseddu, P., Locci, S. & Bonfiglio, A. Towards the textile transistor: Assembly and characterization of an organic field effect transistor with a cylindrical geometry. Appl. Phys. Lett. 89, 1-4 (2006).
Mak, K. F. et al. Measurement of the optical conductivity of graphene. Phys. Rev. Lett. 101, 196405 (2008).
Matsuhisa, N. et al. Printable elastic conductors with a high conductivity for electronic textile applications. Nat. Commun. 6, 7461 (2015).
Mattana, G. et al. Organic electronics on natural cotton fibres. Org. Electron. physics, Mater. Appl. 12, 2033-2039 (2011).
McManus, D. et al. Water-based and biocompatible 2D crystal inks for all-inkjet-printed heterostructures. Nat. Nanotechnol. (2017). doi:10.1038/nnano.2016.281
Nam, S. et al. High-performance low-voltage organic field-effect transistors prepared on electro-polished aluminum wires. ACS Appl. Mater. Interfaces 4, 6-10 (2012).
Nateghi M R, Shateri-Khalilabad M. Silver nanowire-functionalized cotton fabric[J]. Carbohydrate polymers, 2015, 117: 160-168.;
Nathan, A. et al. Flexible electronics: The next ubiquitous platform. in Proceedings of the IEEE 100, 1486-1517 (2012).
Nicolosi, V., Chhowalla, M., Kanatzidis, M. G., Strano, M. S. & Coleman, J. N. Liquid Exfoliation of Layered Materials. Science (80-.). 340, 1226419 (2013).
Nilsson E, Rigdahl M, Hagström B. Electrically conductive polymeric bi-component fibers containing a high load of low-structured carbon black[J]. Journal of Applied Polymer Science, 2015, 132(29).
Novoselov K S, Fal V I, Colombo L, et al. A roadmap for graphene[J]. Nature, 2012, 490(7419): 192-200.
Novoselov, K. S. et al. Electric Field Effect in Atomically Thin Carbon Films. Science (80-.). 306, 666-669 (2004).
Novoselov, K. S. et al. Two-dimensional atomic crystals. Proc. Natl. Acad. Sci. U.S.A 102, 10451-10453 (2005).
Novoselov, K. S. et al. Two-dimensional gas of massless Dirac fermions in graphene. Nature 438, 197-200 (2005).
Novoselov, K. S. Nobel Lecture: Graphene: Materials in the Flatland. Rev. Mod. Phys. 83, 837-849 (2011).
Pasta M, La Mantia F, Hu L, et al. Aqueous supercapacitors on conductive cotton[J]. Nano Research, 2010, 3(6): 452-458
Paton et al. Scalable production of large quantities of defect-free few-layer graphene by shear exfoliation in liquids, Nature Materials 13, 624-630 (2014)
Peng, B. & Chan, P. K. L. Flexible organic transistors on standard printing paper and memory properties induced by floated gate electrode. Org. Electron. physics, Mater. Appl. 15, 203-210 (2014).
Qi, Y. et al. Piezoelectric ribbons printed onto rubber for flexible energy conversion. Nano Lett. 10, 524-525 (2010).
Razaq A, Asif M H, Kalsoom R, et al. Conductive and electroactive composite paper reinforced by coating of polyaniline on lignocelluloses fibers[J]. Journal of Applied Polymer Science, 2015, 132(29).
Reich, S. et al. Resonant Raman scattering in cubic and hexagonal boron nitride. Phys. Rev. B 71, 1-12 (2005).
Ren, J. et al. Environmentally-friendly conductive cotton fabric as flexible strain sensor based on hot press reduced graphene oxide. Carbon N. Y. 111, 622-630 (2017).
Ryntz, R. A. & Yaneff, P. V. Coatings Of Polymers And Plastics. (2003). doi:10.1201/9780203912379
Sainsbury, T. et al. Dibromocarbene functionalization of boron nitride nanosheets: Toward band gap manipulation and nanocomposite applications. Chem. Mater. 26, 7039-7050 (2014).
Schwierz, F. Graphene transistors. Nat. Nanotechnol. 5, 487-496 (2010).
Sekitani, T., Zschieschang, U., Klauk, H. & Someya, T. Flexible organic transistors and circuits with extreme bending stability. Nat. Mater. 9, 1015-1022 (2010).
Sekitani, T.; Yokota, T.; Zschieschang, U.; Klauk, H.; Bauer, S.; Takeuchi, K.; Takamiya, M.; Sakurai, T.; Someya, T. Organic Nonvolatile Memory Transistors for Flexible Sensor Arrays. Science 2009,326,1516-1519.
Shateri-Khalilabad M, Yazdanshenas M E. Fabricating electroconductive cotton textiles using graphene[J]. Carbohydrate polymers, 2013, 96(1): 190-195.
Shen, J. et al. Liquid Phase Exfoliation of Two-Dimensional Materials by Directly Probing and Matching Surface Tension Components. Nano Lett. 15, 5449-5454 (2015).
Singh, M.; Haverinen, H. M.; Dhagat, P.; Jabbour, G. E. Inkjet Printing—Process and Its Applications. Adv. Mater. 2010, 22, 673-685.
Sirringhaus, H.; Kawase, T.; Friend, R. H.; Shimoda, T.; Inbasekaran, M.; Wu, W.; Woo, E. P. High-Resolution Inkjet Printing of All-Polymer Transistor Circuits. Science 2000, 290, 2123-2126.
Su, C. Y. et al. Highly efficient restoration of graphitic structure in graphene oxide using alcohol vapors. ACS Nano 4, 5285-5292 (2010).
Suk, J. W. et al. Enhancement of the electrical properties of graphene grown by chemical vapor deposition via controlling the effects of polymer residue. Nano Lett 13, 1462-1467 (2013).
Torrisi F, Hasan T, Wu W, et al. Inkjet-printed graphene electronics[J]. Acs Nano, 2012, 6(4): 2992-3006.
Tuinstra, F. & Koenig, L. Raman Spectrum of Graphite. J. Chem. Phys. 53, 1126-1130 (1970).
Van Osch, T. H. J.; Perelaer, J.; de Laat, A. W. M.; Schubert, U. S. Inkjet Printing of Narrow Conductive Tracks on Untreated Polymeric Substrates. Adv. Mater. 2008, 20, 343-345.
Vosgueritchian, M., Lipomi, D. J. & Bao, Z. Highly conductive and transparent PEDOT:PSS films with a fluorosurfactant for stretchable and flexible transparent electrodes. Adv. Funct. Mater. 22, 421-428 (2012).
Wang, H., Wu, Y., Cong, C., Shang, J. & Yu, T. Hysteresis of electronic transport in graphene transistors. ACS Nano 4, 7221-7228 (2010).
Wang, L. et al. One-dimensional electrical contact to a two-dimensional material. Science (80-.). 342, 614-7 (2013).
Withers, F. et al. Light-emitting diodes by band-structure engineering in van der Waals heterostructures. Nat Mater 14, 301-306 (2015).
Woltornist S J, Alamer F A, McDannald A, et al. Preparation of conductive graphene/graphite infused fabrics using an interface trapping method[J]. Carbon, 2015, 81: 38-42;
Xia, F., Farmer, D. B., Lin, Y. M. & Avouris, P. Graphene field-effect transistors with high on/off current ratio and large transport band gap at room temperature. Nano Lett. 10, 715-718 (2010).
Xue C H, Chen J, Yin W, et al. Superhydrophobic conductive textiles with antibacterial property by coating fibers with silver nanoparticles[J]. Applied Surface Science, 2012, 258(7): 2468-2472
Yamashita T, Takamatsu S, Miyake K, et al. Fabrication and evaluation of a conductive polymer coated elastomer contact structure for woven electronic textile[J]. Sensors and Actuators A: Physical, 2013, 195: 213-218.
Yan, H. et al. A high-mobility electron-transporting polymer for printed transistors. Nature 457, 679-686 (2009).
Yao, Y. et al. Three-Dimensional Printable High-Temperature and High-Rate Heaters. ACS Nano 10, 5272-5279 (2016).
Zhang, X. et al. Dispersion of graphene in ethanol using a simple solvent exchange method. Chem. Commun. (Camb). 46, 7539-41 (2010).
Zhou, K. G., Mao, N. N., Wang, H. X., Peng, Y. & Zhang, H. L. A mixed-solvent strategy for efficient exfoliation of inorganic graphene analogues. Angew. Chemie—Int. Ed. 50, 10839-10842 (2011).

1. A flexible electronic component comprising a flexible fabric substrate, a smoothing layer formed on the flexible fabric substrate and a deposited layer of nanoplatelets derived from a layered material formed on the smoothing layer.

2. The flexible electronic component according to claim 1 wherein said deposited layer of nanoplatelets forms a first layer of a first nanoplatelet material and there is provided at least a second layer, of a different nanoplatelet material, formed at least in part on the first layer.

3. The flexible electronic component according to claim 2 wherein there are additionally provided at least first and second electrodes, in contact respectively with the first and second layers.

4. The flexible electronic component according to claim 1 in the form of a transistor.

5. The flexible electronic component according to claim 1 in the form of a field effect transistor.

6. The flexible electronic component according to claim 2 wherein the first layer is formed of graphene and the second layer is formed of h-BN.

7. The flexible electronic component according to claim 6 wherein the first layer is provided with source and drain electrodes and the second layer is provided with a gate electrode, the source, drain and gate electrodes being separated from the interface between the first layer and the second layer.

8. The flexible electronic component according to claim 2 wherein the first layer is formed of h-BN and the second layer is formed of graphene.

9. The flexible electronic component according to claim 8 wherein the first layer is provided with a gate electrode and the second layer is provided with source and drain electrodes, the source, drain and gate electrodes being separated from the interface between the first layer and the second layer.

10. The flexible electronic component according to claim 6 having a charge carrier mobility of at least 50 cm²/Vs.

11. The flexible electronic component according to claim 1 wherein the fabric, before application of the smoothing layer, has a roughness Rq of 35 μm or less.

12. The flexible electronic component according to claim 1 wherein the fabric is a polyester satin.

13. The flexible electronic component according to claim 1 wherein the smoothing layer is formed from polyurethane.

14. The flexible electronic component according to claim 1 wherein the smoothing layer comprises a first sub-layer of polyurethane and a second sub-layer of h-BN.

15. The flexible electronic component according to claim 1 wherein the thickness of the smoothing layer is at least 5 μm.

16. The flexible electronic component according to claim 1 further comprising a washable protective layer formed over the device.

17. A method for producing a flexible electronic component, the method including the steps:
treating a flexible fabric substrate to provide an intermediate smoothing layer on at least a part of the flexible fabric substrate;
providing an ink comprising a dispersion of nanoplatelets suspended in a carrier liquid, the nanoplatelets being derived from a layered material;
applying the ink to at least a part of the intermediate smoothing layer to produce the electronic component.

18. The method according to claim 17 wherein the nanoplatelets include graphene nanoplatelets.

19. The method according to claim 17 wherein the intermediate smoothing layer applied to the fabric substrate has a surface roughness Rq of <10 μm.

20. The method according to claim 17 wherein multiple sub-layers of the same nanoplatelet material are deposited, in order to build up a required thickness for the nanoplatelet material layer.

21. The method according to claim 17 wherein the intermediate smoothing layer is formed by deposition of multiple sub-layers, in order to build up a required thickness for the intermediate smoothing layer.

22. The method according to claim 17 wherein the ink is applied to the at least a part of the treated portion of the fabric substrate by inkjet printing.

23. A method for producing a flexible electronic component, the method including the steps:
providing a flexible fabric substrate;
treating at least a part of the flexible fabric substrate to provide a treated portion wherein the treated portion is cationized or anionized;
providing an ink comprising a dispersion of nanoplatelets suspended in a carrier liquid, the nanoplatelets being derived from a layered material;
applying the ink to at least a part of the treated portion of the fabric substrate to produce the electronic component.

24. The method according to claim 23 wherein the nanoplatelets are functionalized.

25. The method according to claim 23, wherein the nanoplatelets include graphene nanoplatelets.

26. The method according to claim 23, wherein the step of treating the at least a part of the flexible fabric substrate includes a step of contacting the at least a part of flexible fabric substrate with a solution comprising one or more quaternary ammonium salt.

27. The method according to claim 23 wherein the ink is applied to the at least a part of the treated portion of the fabric substrate by inkjet printing.

28. The method according to claim 23 wherein a flexible polymer layer is coated on top of the electronic component or device to protect the electronic component or device and preserve one or more of the electrical, optical and mechanical properties of the electronic component or device.

29. (canceled)
